(19) United States
(12) Patent Application Publication
(10) Pub. No.: US 2023/0387023 A1
(43) Pub. Date: Nov. 30, 2023

(54) MEMORY DEVICE INCLUDING CONTACT STRUCTURES HAVING MULTI-LAYER DIELECTRIC LINER

(71) Applicant: Micron Technology, Inc., Boise, ID (US)

(72) Inventor: Shuangqiang Luo, Boise, ID (US)

(21) Appl. No.: 17/826,776

(22) Filed: May 27, 2022

(51) Int. Cl. H01L 23/535; H01L 27/11556; H01L 27/11529; H01L 27/11582; H01L 27/11573

(52) U.S. Cl. CPC H01L 23/535; H01L 27/11556; H01L 27/11529; H01L 27/11582; H01L 27/11573

(57) ABSTRACT

Some embodiments include apparatuses and methods of forming the apparatuses. One of the apparatuses includes tiers located one over another, the tiers including respective memory cells and control gates for the memory cells; conductive contacts contacting the control gates, the conductive contacts having different lengths extending in a direction from one tier to another tier among the tiers; and a contact structure adjacent one of the conductive contacts. The contact structure includes a conductive core portion extending through the tiers and separated from the control gates, and a dielectric liner portion adjacent the conductive core portion. The dielectric liner portion includes a first dielectric material, a second dielectric material adjacent the first dielectric material, and a third dielectric material adjacent the second dielectric material.

### FIELD

Embodiments described herein relate to memory devices including vertical conductive structures in memory blocks.

### BACKGROUND

Some conventional memory devices have vertical conductive structures as part of conductive paths that provide electrical signals between elements of the memory device. As features in the memory device are reduced in part to increase memory density, dimensions between such conductive structures are also reduced. At a certain reduced dimension, defects such as electrical shorts between may occur between adjacent conductive structures. This can lead to unreliable memory devices and reduced yield.

### BRIEF DESCRIPTION OF THE DRAWINGS

FIG. 1 shows an apparatus in the form of a memory device, according to some embodiments described herein.

FIG. 2 shows a schematic of a memory device having a memory array and memory cell blocks, according to some embodiments described herein.

FIG. 3A shows a top view of a structure of the memory device of FIG. 2 including the memory array, staircase regions, and dielectric structures between respective blocks of the memory device, according to some embodiments described herein.

FIG. 3B shows detail of a portion of the memory device of FIG. 3A, according to some embodiments described herein.

FIG. 3C shows a portion (e.g., a side view) of the memory device of FIG. 3B, according to some embodiments described herein.

FIG. 3D and FIG. 3E show details (e.g., side view and top view, respectively) of a contact structure of the memory device of FIG. 3C, according to some embodiments described herein.

FIG. 3F and FIG. 3G show details (e.g., side view and top view, respectively) of a conductive contact (e.g., word line contact) of the memory device of FIG. 3C, according to some embodiments described herein.

FIG. 4 through FIG. 20 show different views of structures during processes of forming the memory device of FIG. 2 through FIG. 3G, according to some embodiments described herein.

### DETAILED DESCRIPTION

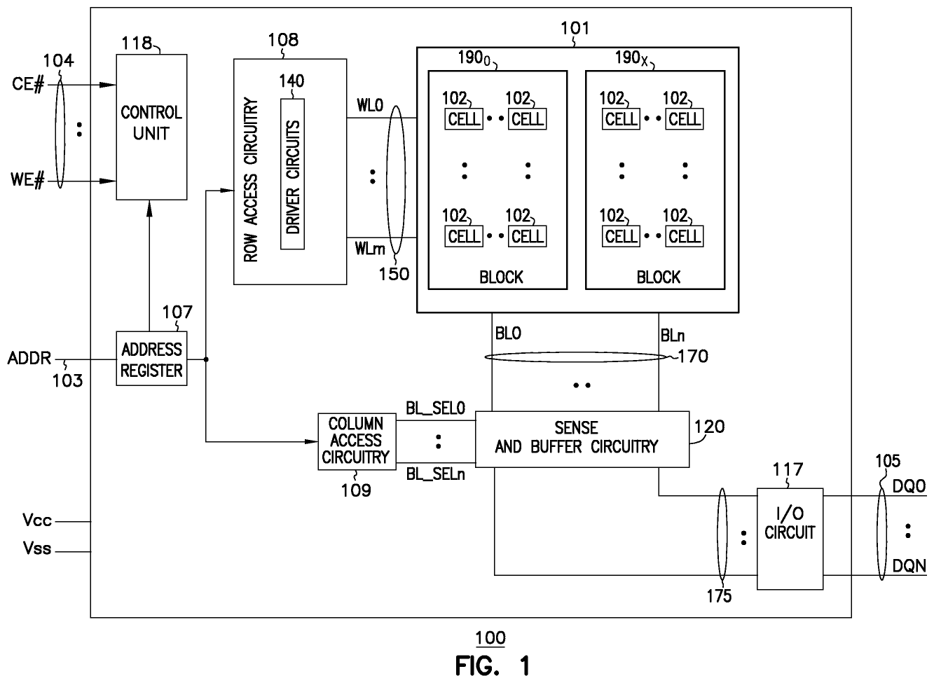

The techniques described herein involve a memory device having conductive contacts and adjacent contact structures that include respective vertical pillars. The contact structures are part of conductive paths coupled to control gates (e.g., word lines) for memory cells in memory blocks of the memory device. The contact structures are part of additional conductive paths between other components in the memory device. As described above, some conventional memory devices may include similar structures that may be susceptible to damage at a certain device dimension. In the memory device described herein, the conductive contacts and contact structures have improved structures that are less susceptible to be damaged during their formation. In some examples described herein, each of the conductive contact and the contact structure includes a dielectric liner portion and a conductive core portion surrounded by the dielectric liner portion. Structuring the conductive contact and the contact structure, as described in more detail below, can reduce or mitigate potential defects involving the contact structures and adjacent contact structures. This leads to a reliable memory device, improved yield, an option for features (e.g., block size) of the memory device to be scaled (e.g., reduced). Other improvements and benefits of the described techniques are further discussed below with reference to FIG. 1 through FIG. 20.

FIG. 1 shows an apparatus in the form of a memory device 100, according to some embodiments described herein. Memory device 100 can include a memory array (or multiple memory arrays) 101 containing memory cells 102 arranged in blocks (blocks of memory cells), such as blocks 190₀ through 190ₓ (e.g., there are X+1 blocks in memory device 100). In the physical structure of memory device 100, memory cells 102 can be arranged vertically (e.g., stacked one over another) over a substrate (e.g., a semiconductor substrate) of memory device 100.

As shown in FIG. 1, memory device 100 can include access lines 150 and data lines 170. Access lines 150 can include word lines, which can include global word lines and local word lines (e.g., control gates). Data lines 170 can include bit lines (e.g., local bit lines). Access lines 150 can carry signals (e.g., word line signals) WL0 through WLm. Data lines 170 can carry signals (e.g., bit line signals) BL0 through BLn. Memory device 100 can use access lines 150 to selectively access memory cells 102 of blocks 190₀ through 190ₓ and data lines 170 to selectively exchange information (e.g., data) with memory cells 102.

Memory device 100 can include an address register 107 to receive address information (e.g., address signals) ADDR on lines (e.g., address lines) 103. Memory device 100 can include row access circuitry 108 and column access circuitry 109 that can decode address information from address register 107. Based on decoded address information, memory device 100 can determine which memory cells 102 of which blocks 190₀ through 190ₓ are to be accessed during a memory operation. Memory device 100 can include drivers (driver circuits) 140, which can be part of row access circuitry 108. Drivers 140 can operate (e.g., operate as switches) to form (or not to form) conductive paths (e.g., current paths) between nodes (e.g., global access lines) providing voltages and respective access lines 150 during operations of memory device 100.

Memory device 100 can perform a read operation to read (e.g., sense) information (e.g., previously stored information) from memory cells 102 of blocks 190₀ through 190ₓ, or a write (e.g., programming) operation to store (e.g., program) information in memory cells 102 of blocks 190₀ through 190ₓ. Memory device 100 can use data lines 170 associated with signals BL0 through BLn to provide information to be stored in memory cells 102 or obtain information read (e.g., sensed) from memory cells 102. Memory device 100 can also perform an erase operation to erase information from some or all of memory cells 102 of blocks 190₀ through 190ₓ.

Memory device 100 can include a control unit 118 that can be configured to control memory operations of memory device 100 based on control signals on lines 104. Examples of the control signals on lines 104 include one or more clock signals and other signals (e.g., a chip-enable signal CE #, a write-enable signal WE #) to indicate which operation (e.g., read, write, or erase operation) memory device 100 can perform. Other devices external to memory device 100 (e.g., a memory controller or a processor) may control the values of the control signals on lines 104. Specific values of a combination of the signals on lines 104 may produce a command (e.g., read, write, or erase command) that may cause memory device 100 to perform a corresponding memory operation (e.g., read, write, or erase operation).

Memory device 100 can include sense and buffer circuitry 120 that can include components such as sense amplifiers and page buffer circuits (e.g., data latches). Sense and buffer circuitry 120 can respond to signals BL_SEL0 through BL_SELn from column access circuitry 109. Sense and buffer circuitry 120 can be configured to determine (e.g., by sensing) the value of information read from memory cells 102 (e.g., during a read operation) of blocks 190₀ through 190ₓ and provide the value of the information to lines 175, which can include global data lines (e.g., global bit lines). Sense and buffer circuitry 120 can also be configured to use signals on lines 175 to determine the value of information to be stored (e.g., programmed) in memory cells 102 of blocks 190₀ through 190ₓ (e.g., during a write operation) based on the values (e.g., voltage values) of signals on lines 175 (e.g., during a write operation).

Memory device 100 can include input/output (I/O) circuitry 117 to exchange information between memory cells 102 of blocks 190₀ through 190ₓ and lines (e.g., I/O lines) 105. Signals DQ0 through DQN on lines 105 can represent information read from or stored in memory cells 102 of blocks 190₀ through 190ₓ. Lines 105 can include nodes within memory device 100 or pins (or solder balls) on a package where memory device 100 can reside. Other devices external to memory device 100 (e.g., a memory controller or a processor) can communicate with memory device 100 through lines 103, 104, and 105.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or alternating current to direct current (AC-DC) converter circuitry.

Each of memory cells 102 can be programmed to store information representing a value of at most one bit (e.g., a single bit), or a value of multiple bits such as two, three, four, or another number of bits. For example, each of memory cells 102 can be programmed to store information representing a binary value “0” or “1” of a single bit. The single bit per cell is sometimes called a single-level cell. In another example, each of memory cells 102 can be programmed to store information representing a value for multiple bits, such as one of four possible values “00”, “01”, “10”, and “11” of two bits, one of eight possible values “000”, “001”, “010”, “011”, “100”, “101”, “110”, and “111” of three bits, or one of other values of another number of multiple bits. A cell that has the ability to store multiple bits is sometimes called a multi-level cell (or multi-state cell).

Memory device 100 can include a non-volatile memory device, and memory cells 102 can include non-volatile memory cells, such that memory cells 102 can retain information stored thereon when power (e.g., voltage Vcc, Vss, or both) is disconnected from memory device 100. For example, memory device 100 can be a flash memory device, such as a NAND flash (e.g., 3-dimensional (3-D) NAND) or a NOR flash memory device, or another kind of memory device, such as a variable resistance memory device (e.g., a phase change memory device or a resistive Random-Access Memory (RAM) device.

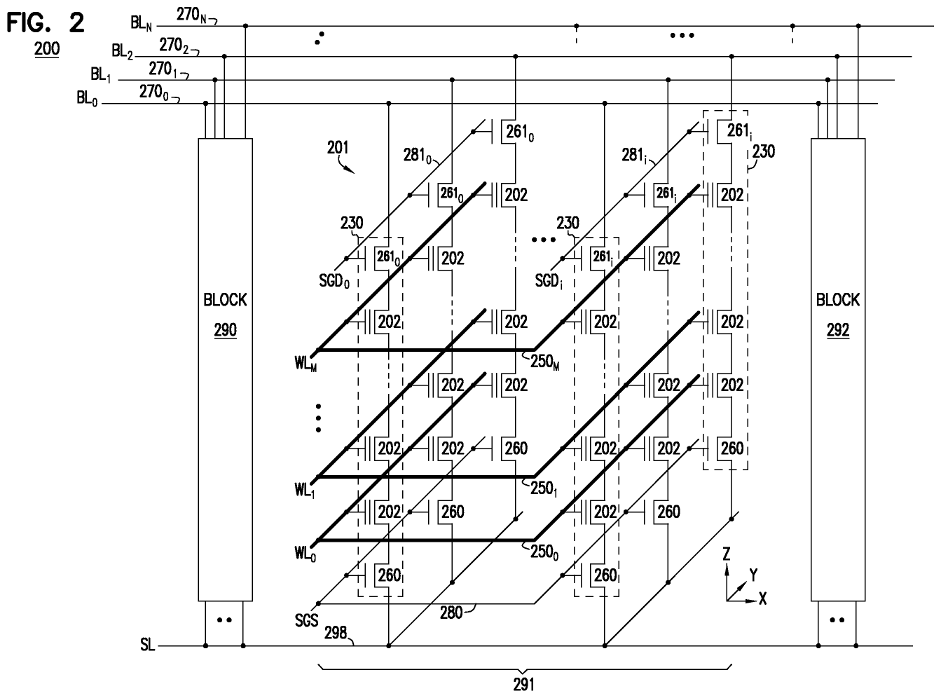

One of ordinary skill in the art may recognize that memory device 100 may include other components, several of which are not shown in FIG. 1 so as not to obscure the example embodiments described herein. At least a portion of memory device 100 can include structures and perform operations similar to or identical to the structures and operations of any of the memory devices described below with reference to FIG. 2 through FIG. 20.

FIG. 2 shows a schematic of a memory device 200 having a memory array 201, and blocks (e.g., memory cell blocks) 290, 291, and 292, according to some embodiments described herein. For simplicity, only detail for elements of block 291 is shown in FIG. 2. Blocks 290 and 292 have similar elements as block 291.

Memory device 200 can include a non-volatile (e.g., NAND flash memory device) or other types of memory devices. Memory device 200 can correspond to memory device 100. For example, memory array (or multiple memory arrays) 201 and blocks 290, 291, and 292 can correspond to memory array 101 and three of blocks 190₀ through 190ₓ, respectively, of memory device 100 of FIG. 1.

As shown in FIG. 2, memory device 200 can include memory cells 202, data lines 270₀ through 270_{N} (270₀-270_{N}), and control gates 250₀ through 250M in block 291. Data lines 270₀-270_{N} can correspond to part of data lines 170 of memory device 100 of FIG. 1. In FIG. 2, label “N” (index N) next to a number (e.g., 270_{N}) represents the number of data lines of memory device 200. For example, if memory device 200 includes 16 data lines, then N is 15 (data lines 270₀ through 270₁₅). In FIG. 2, label “M” (index M) next to a number (e.g., 250_{M}) represents the number of control gates of memory device 200. For example, if memory device 200 includes 128 control gates, then M is 127 (control gates 250₀ through 250₁₂₇). Memory device 200 can have the same number of control gates (e.g., M−1 control gates) among the blocks (e.g., blocks 290, 291, and 292) of memory device 200.

In FIG. 2, data lines 270₀-270_{N} can include (or can be part of) bit lines (e.g., local bit lines) of memory device 200. As shown in FIG. 2, data lines 270₀-270_{N} can carry signals (e.g., bit line signals) BL₀ through BL_{N}, respectively. In the physical structure of memory device 200, data lines 270₀-270_{N} can be structured as conductive lines and have respective lengths extending in the Y-direction (e.g., a direction from one memory block to another).

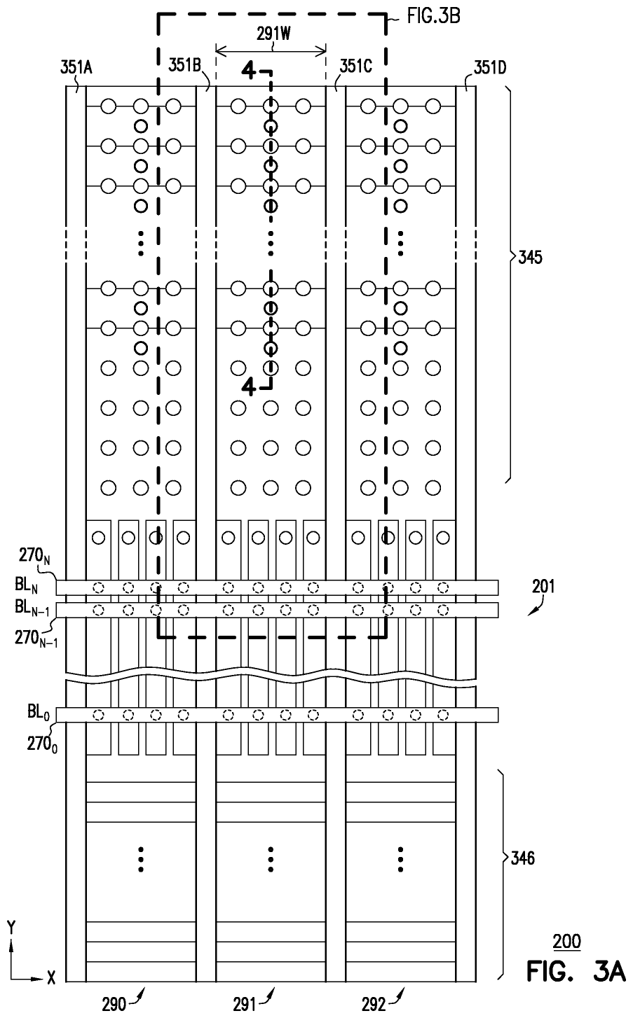

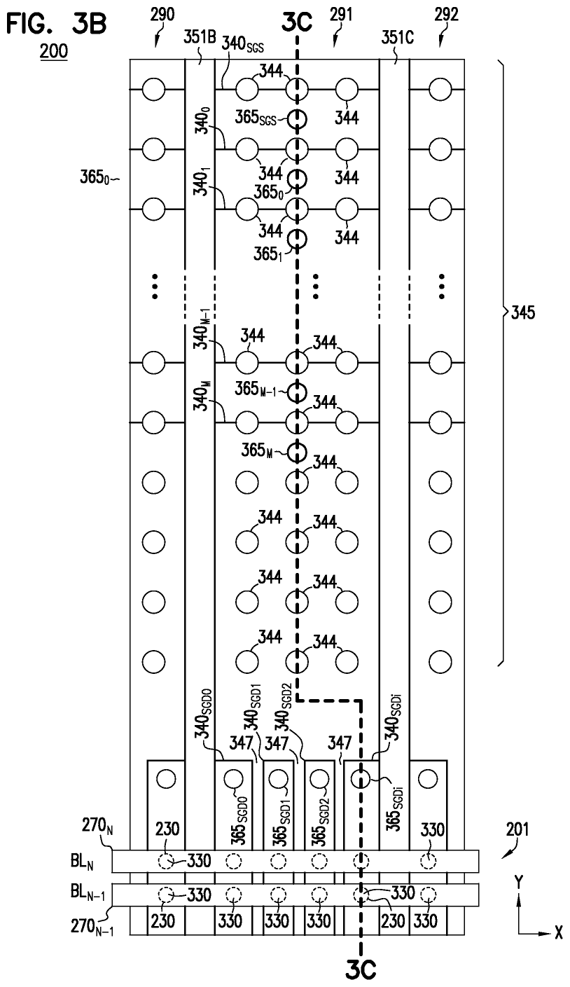

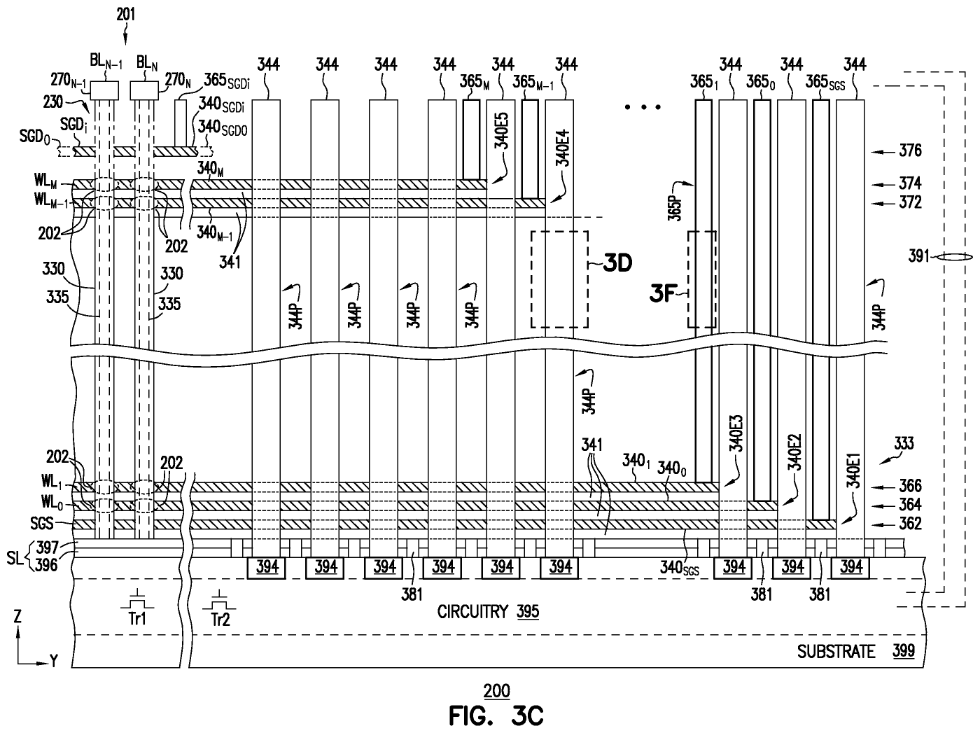

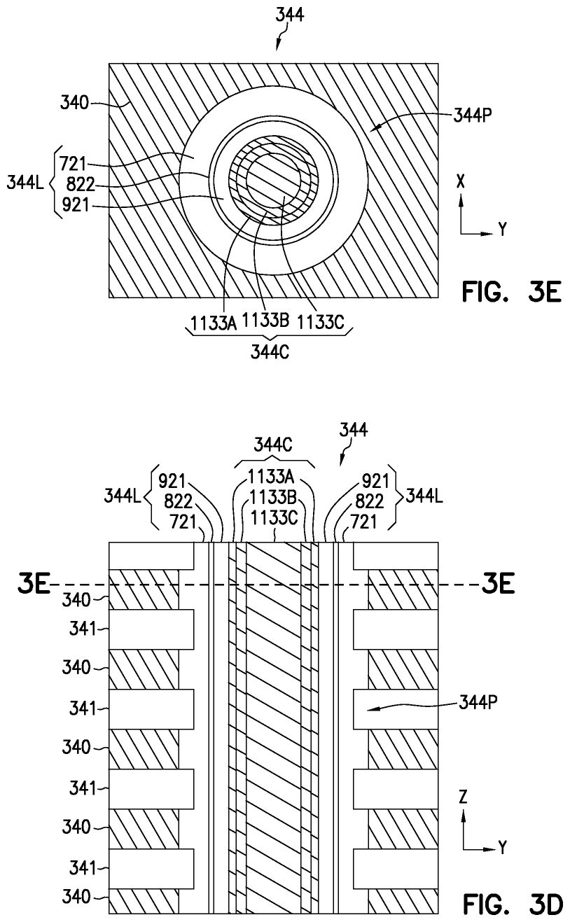

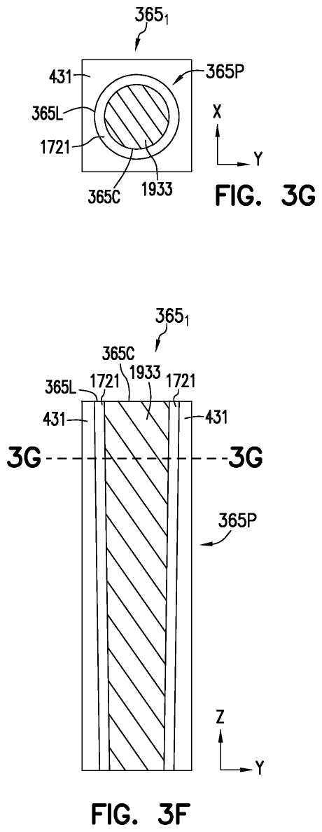

FIG. 2 shows directions X, Y, and Z that can be relative to the physical directions (e.g., dimensions) of the structure of memory device 200. For example, the Z-direction can be a direction perpendicular to (e.g., vertical direction with respect to) a substrate of memory device 200 (e.g., a substrate 399 shown in FIG. 3C). The Z-direction is perpendicular to the X-direction and Y-direction (e.g., the Z-direction is perpendicular to an X-Y plane of memory device 200).

As shown in FIG. 2, memory cells 202 can be organized into separate blocks (memory blocks or blocks of memory cells) such as blocks 290, 291, and 292. FIG. 2 shows memory device 200 including three blocks 290, 291, and 292 as an example. However, memory device 200 can include numerous blocks. The blocks (e.g., blocks 290, 291, and 292) of memory device 200 can share data lines (e.g., data lines 270₀-270_{N}) to carry information (in the form of signals) read from or to be stored in memory cells of selected memory cells (e.g., selected memory cells in block 290, 291, or 292) of memory device 200.

Control gates 250₀-250_{M} in block 291 can be part of access lines (e.g., word lines). The access lines (that include control gates 250₀-250_{M}) of memory device 200 can correspond to access lines 150 of memory device 100 of FIG. 1.

Other blocks (e.g., blocks 290 and 292) of memory device 200 can have control gates similar to (or the same as) control gates 250₀-250_{M} of block 291. Blocks 290, 291, and 292 can be accessed separately (e.g., accessed one block at a time). For example, block 291 can be accessed at one time using control gates 250₀-250_{M}, and block 290 or 291 can be accessed at another time using control gates in the respective block.

In the physical structure of memory device 200, control gates 250₀-250_{M} can be formed on different levels (e.g., layers) of memory device 200 in the Z-direction. In this example, the levels (e.g., layers) of control gates 250₀-250_{M} can be formed (e.g., stacked) one level (one layer of material) over another (another layer of material) in the Z-direction.

As shown in FIG. 2, memory cells 202 can be included in respective memory cell strings 230. For simplicity, only three memory cell strings 230 are labeled in FIG. 2. Each of memory cell strings 230 can have series-connected memory cells (e.g., M+1 (e.g., 128) series-connected memory cells) in the Z-direction. In a physical structure of memory device 200, memory cells 202 in each of memory cell strings 230 can be formed (e.g., stacked vertically one over another) in different levels (physical portions) of memory device 200. The levels of memory device 200 can be included in (or can correspond to) respective tiers (stacked one over another in the Z-direction) of memory device 200. In the example of FIG. 2, memory device 200 can include M+1 tiers (e.g., 128 tiers, where M=127) of memory cells and respective control gates. The number of memory cells 202 in each of memory cell strings 230 can be equal to the number of levels (e.g., the number of tiers). Thus, in the example of FIG. 2, there can be 128 levels (layers) of memory cells 202 in the Z-direction.

The number of memory cells 202 in each of memory cell strings 230 can also be equal to the number of levels (e.g., the number of tiers) of control gates (e.g., control gates 250₀-250_{M}) of memory device 200. For example, if each memory cell string 230 has 128 (e.g., M=127) memory cells 202, then there are 128 corresponding levels (e.g., 128 tiers) of control gates 250₀-250_{M} for the 128 memory cells.

As shown in FIG. 2, control gates 250₀-250_{M} can carry corresponding signals WL₀-WL_{M}. As mentioned above, control gates 250₀-250_{M} can include (or can be parts of) access lines (e.g., word lines) of memory device 200. Each of control gates 250₀-250_{M} can be part of a structure (e.g., a level) of a conductive material (e.g., a layer of conductive material) located in a level of memory device 200. Memory device 200 can use signals WL₀-WL_{M} to selectively control access to memory cells 202 of block 291 during an operation (e.g., read, write, or erase operation). For example, during a read operation, memory device 200 can use signals WL₀-WL_{M} to control access to memory cells 202 of block 291 to read (e.g., sense) information (e.g., previously stored information) from memory cells 202 of block 291. In another example, during a write operation, memory device 200 can use signals WL₀-WL_{M} to control access to memory cells 202 of block 291 to store information in memory cells 202 of block 291.

As shown in FIG. 2, memory cells in different memory cell strings in block 291 can share (e.g., can be controlled by) the same control gate in block 291. For example, memory cells 202 (of different memory cell strings 230) coupled to control gate 250₀ can share (can be controlled by) control gate 250₀. In another example, memory cells 202 (of different memory cell strings 230) coupled to control gate 250₁ can share (can be controlled by) control gate 250₁.

Memory device 200 can include a source (e.g., a source line, a source plate, or a source region) 298 that can carry a signal (e.g., a source line signal) SL. Source 298 can include (e.g., can be formed from) a conductive structure (e.g., conductive region) of memory device 200. The conductive structure of source 298 can include multiple levels (e.g., layers) of conductive materials stacked one over another over a substrate of memory device 200. Source 298 can be common conductive structure (e.g., common source plate or common source region) of block 290, 291, and 292. Source 298 can be coupled to a ground connection (e.g., ground plate) of memory device 200. Alternatively, source 298 can be coupled to a connection (e.g., a conductive region) that is different from a ground connection.

As shown in FIG. 2, memory device 200 can include select transistors (e.g., drain select transistors) 261₀ through 261ᵢ (261₀-261ᵢ) and select gates (e.g., drain select gates) 281₀ through 281ᵢ in block 291. Transistors 261₀ can share the same select gate 281₀. Transistors 261ᵢ can share the same select gate 281ᵢ. Select gates 281₀-281ᵢ can carry signals SGD₀ through SGDᵢ (SGD₀-SGDᵢ), respectively.

Transistors 261₀-261ᵢ can be controlled (e.g., turned on or turned off) by signals SGD₀-SGDᵢ, respectively. During a memory operation (e.g., a read or write operation) of memory device 200, transistors 261₀ and transistors 261ᵢ can be turned on one group at a time (e.g., either the group of transistors 261₀ or the group of transistors 261ᵢ can be turned on at a particular time). Transistors 261₀ can be turned on (e.g., by activating signal SGD₀) to couple memory cell strings 230 of block 291 to respective data lines 270₀-270_{N}. Transistors 261ᵢ can be turned on (e.g., by activating signal SGDᵢ) to couple memory cell strings 230 of block 291 to respective data lines 270₀-270_{N}. Transistors 261₀-261ᵢ can be turned off (e.g., by deactivating signals SGD0-SGDi) to decouple the memory cell strings 230 of block 291 from respective data lines 270₀-270_{N}.

Memory device 200 can include transistors (e.g., source select transistors) 260 in block 291, each of which can be coupled between source 298 and memory cells 202 in a respective memory cell string (one of memory cell strings 230) of block 291. Memory device 200 can include a select gate (e.g., source select gate) 280 that can be shared by transistors 260. Transistors 260 can be controlled (e.g., turned on or turned off) by the same signal, such as SGS signal (e.g., source select gate signal) provided on select gate 280. During a memory operation (e.g., a read or write operation) of memory device 200, transistors 260 can be turned on (e.g., by activating an SGS signal) to couple memory cell strings 230 to source 298. Transistors 260 can be turned off (e.g., by deactivating the SGS signal) to decouple memory cell strings 20 from source 298.

Memory device 200 includes other components, which are not shown in FIG. 2 so as not to obscure the example embodiments described herein. Some of the structures of memory device 200 are described below with reference to FIG. 3A through FIG. 20. For simplicity, detailed description of the same element among the drawings (FIG. 1 through FIG. 20) is not repeated.

FIG. 3A shows a top view of a structure of memory device 200 including a memory array (memory cell array) 201, staircase regions 345 and 346, and dielectric structures (e.g., block dividers) 351A, 351B, 351C, and 351D between respective blocks 290, 291, and 292, according to some embodiments described herein.

In the figures (drawings) herein, similar or the same elements of memory device 200 of FIG. 2 and other figures (e.g., FIG. 3A through FIG. 20) are given the same labels. Detailed descriptions of similar or the same elements may not be repeated from one figure to another figure. For simplicity, cross-sectional lines (e.g., hatch lines) are omitted from some or all the elements shown in the drawings described herein. Some elements of memory device 200 may be omitted from a particular figure of the drawings so as not to obscure the view or the description of the element (or elements) being described in that particular figure. Further, the dimensions (e.g., physical structures) of the elements shown in the drawings described herein are not scaled.

As shown in FIG. 3A, blocks (blocks of memory cells) 290, 291, and 292 of memory device 200 can be located side-by-side from one block to another in the X-direction. Three blocks 290, 291, and 292 are shown as an example. Memory device 200 can include numerous blocks. Block 291 of FIG. 3A is schematically shown and described above with reference to FIG. 2.

In FIG. 3A, each of blocks 290, 291, and 292 has width in the X-direction, which is a direction from one block to another. For example, block 291 has a width 291W. As shown in FIG. 3A, the direction from one block to another is also a direction from one dielectric structure to another dielectric structure (among dielectric structures 351A, 351B, 351C, and 351D).

In FIG. 3A, dielectric structures 351A, 351B, 351C, and 351D can be formed to divide (e.g., organize) memory device 200 into physical blocks (e.g., blocks 290, 291, and 292). Dielectric structures 351A, 351B, 351C, and 351D can have lengths extending in the Y-direction. Each of dielectric structures 351A, 351B, 351C, and 351D can include (or can be formed in) a slit (not labeled) between two adjacent blocks. The slit can have sidewalls (e.g., edges) opposing each other in the X-direction and adjacent two respective blocks. The slit can include (or can be) a trench having a depth in the Z-direction. For example, dielectric structure 351B can be formed (e.g., located) in a slit between blocks 290 and 291, in which the slit can have opposing sidewalls (e.g., edges) adjacent respective blocks 290 and 291. Dielectric structure 351C can be formed in a slit between blocks 291 and 292, in which the slit can have opposing sidewalls adjacent respective blocks 291 and 292. Other dielectric structures 351A and 351D can be located adjacent respective blocks shown in FIG. 3A.

Each of dielectric structures 351A, 351B, 351C, and 351D can include a dielectric material (or dielectric materials) formed in (e.g., filling) a respective slit. Dielectric structures 351A, 351B, 351C, and 351D can separate (e.g., physically and electrically separate) one block from another. For example, as shown in FIG. 3A, dielectric structure 351B can separate block 291 from block 290. Dielectric structure 351C can separate block 291 from block 292.

As shown in FIG. 3A, data lines 270₀ through 270_{N} (associated with signals BL₀ through BL_{N}) of memory device 200 can be located over blocks 290, 291, and 292 (with respect to the Z-direction). Data lines 270₀ through 270_{N} can have respective lengths extending in the X-direction. Data lines 270₀ through 270_{N} can extend over (e.g., on top of) and across (in the X-direction) blocks 290, 291, and 292 and can be shared by blocks 290, 291, and 292.

Staircase regions 345 and 346 of memory device 200 can be located on respective sides (in the Y-direction) of memory array 201. Staircase regions 345 and 346 are part of memory device 200 where conductive contacts (labeled in FIG. 3B, e.g., conductive contacts 365_{SGS}, 365₀, 365₁, 365_{M-1}, 365_{M}, and 365_{SGD0} through 365_{SGDi}) can be formed to provide electrical connections (e.g., signals) to respective select gates and control gates (e.g., shown in FIG. 2 as select gates 280, 281₀ and 281ᵢ and control gates 250₀ through 250_{M}) in respective blocks 290, 291, and 292 of memory device 200. Staircase regions 345 and 346 can also include other structures (e.g., contact structures 344, described below).

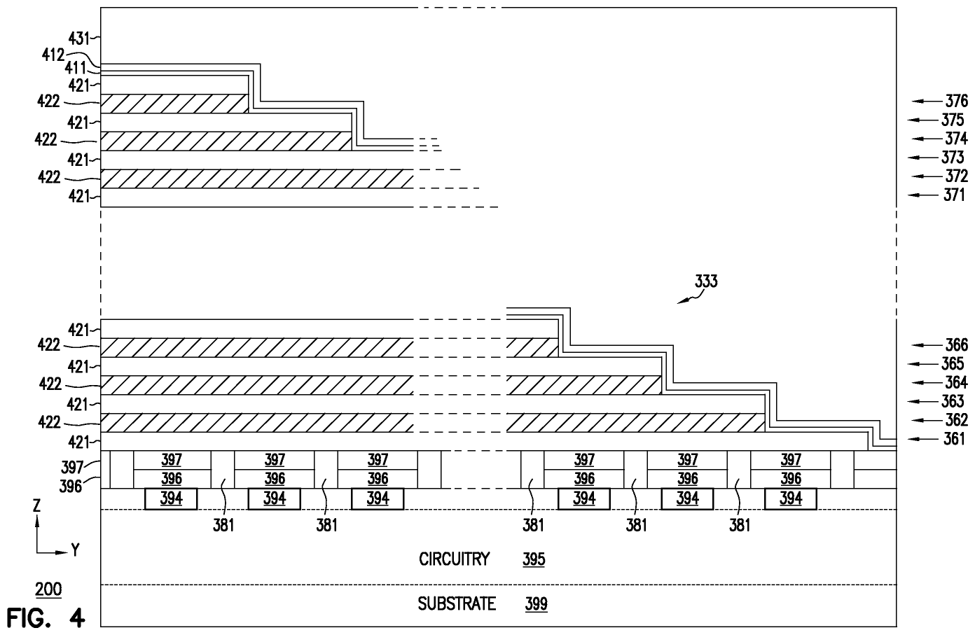

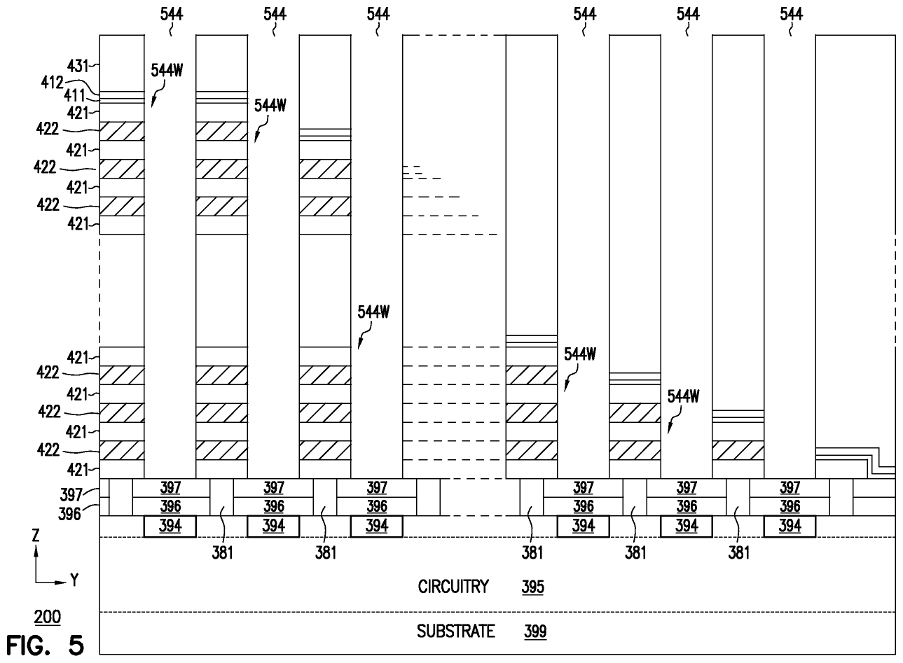

In FIG. 3A, staircase regions 345 and 346 can include similar structures. However, for simplicity, details of staircase region 346 are omitted from the description herein. In an alternative structure of memory device 200, staircase region 346 can be omitted from memory device 200, such that only staircase region 345 (and not both staircase regions 345 and 346) is included in memory device 200. A portion labeled “FIG. 3B” in FIG. 3A is shown in detail in FIG. 3B. Line 4-4 in FIG. 3A shows a location of a portion (e.g., a side view (e.g., a cross-section)) of memory device 200 during processes of forming part of memory device 200 as described below with reference to FIG. 4 through FIG. 20.

As shown in FIG. 3B, memory device 200 can include pillars 330 (shown in top view) in each of block 290, 291, and 292. Pillars 330 are memory cell pillars. The structure of pillars 330 is different from the structure of the pillars of contact structures 344 (described below) and the structure of the pillars of conductive contacts (e.g., conductive contacts 365_{SGS}, 365₀ through 365_{M} and 365_{SGD0} through 365_{SGDi}) of memory device 200. Each pillar 330 is part of a respective memory cell string 230 (also schematically shown in FIG. 2). Conductive contacts 365₀ through 365_{M} can be called word line contacts (or local word line contacts). For simplicity, only conductive contacts 365₀, 365₁, 365_{M-1}, and 365_{M} among conductive contacts 365₀ through 365_{M} (365₀-365_{M}) are shown in FIG. 3B and other figures described herein.

As shown in FIG. 3B, pillars (memory cell pillars) 330 can be located under (below) and coupled to respective data lines (only data lines 270_{N-1} and 270_{N} are shown). Memory cells 202 of a memory cell string can be located (e.g., can be formed vertically) long the length (shown in FIG. 3C) of a corresponding pillar 330. Pillars 330 (and associated memory cell strings) of blocks 290, 291, and 292 can share data lines 270₀ through 270_{N}.

As shown in FIG. 3B, data lines 270₀ through 270_{N} (associated with signals BL₀ through BL_{N}) of memory device 200 can be located over (above) pillars 330 (and over associated memory cell strings) in memory array 201. Data lines 270₀ through 270_{N} can be coupled to respective pillars 330 (which are located under data lines 270₀ through 270_{N} in the Z-direction).

As mentioned above, memory device 200 can include contact structures 344 in each of blocks 290, 291, and 292. For simplicity, FIG. 3B does not give labels for all contact structures 344. As shown in FIG. 3B, contact structures 344 can be located (e.g., can be formed) in respective rows in which each row can include many contact structures 344 in the Y-direction. FIG. 3B shows block 291 including three rows (e.g., left, middle, and right rows in the X-direction) of contact structures 344 as an example. However, block 291 (and other blocks) of memory device 200 can include a different number of rows of contact structures 344.

As shown in FIG. 3B, contact structures 344 and conductive contacts 365_{SGS}, and 365₀-365_{M} can be adjacent each other. For example, one conductive contact (e.g., conductive contact 365₀) can be adjacent and between two contact structures 344. One contact structure 344 can be adjacent and between two contact structures (e.g., conductive contacts 365₀ and 365ᵢ).

As shown in FIG. 3B (e.g., viewing from a direction perpendicular to the X-Y plane (e.g., top view)), conductive contacts 365_{SGS}, 365₀-365_{M}, and 365_{SGD0}-365_{SGDi} can have a circular shape. For example, the boundary of a cross-section of each conductive contact (e.g., conductive contact 365_{M}) has a circular boundary when viewed from a direction perpendicular to the X-Y plane.

FIG. 3B shows an example where each of contact structures 344 can also have a circular shape. For example, the boundary of a cross-section of each contact structure 344 has a circular boundary when viewed from a direction perpendicular to the X-Y plane. However, the boundary of a cross-section of each of contact structures 344 can have a shape different from a circular shape. As an example, each of contact structures 344 can have an oval or oval-like shape, a rectangular or rectangular-like shape (e.g., rectangular having rounded corners), or other shapes.

As mentioned above, conductive contacts 365_{SGS}, 365₀-365_{M}, and 365_{SGD0}-365_{SGDi} in FIG. 3B can be formed to provide electrical connections (e.g., signals) to respective select gates and control gates (e.g., select gates 280, 281₀ and 281ᵢ and control gates 250₀ through 250_{M} of FIG. 2) of memory device 200.

Contact structures 344 in FIG. 3B can be formed to provide electrical connections (e.g., to form part of respective conductive paths) between circuitry (e.g., circuitry 395 in FIG. 3C) of memory device 200 and other elements of memory device 200.

As shown in FIG. 3B, memory device 200 can include conductive materials 340_{SGS}, 340₀ through 340_{M}, and 340_{SGD0}, 340_{SGD1} and 340_{SGD2} and 340_{SGDi} (340_{SGD0} through 340_{SGDi} or 340_{SGD0}-340_{SGDi}) in block 291 that can form (e.g., can be materials included in) respective select gate (e.g., source select gate) 280, control gates 250₀ through 250_{M}, and select gates (e.g., drain select gates) 280₀ and 280, (FIG. 2). For simplicity, only conductive materials 340₀, 340₁, 340_{M-1}, and 340_{M} among conductive materials 340₀ through 340_{M} (340₀-340_{M}) are shown in FIG. 3B and other figures described herein.

In FIG. 3B, conductive materials (e.g., four separate conductive materials) 340_{SGD0}, 340_{SGD1}, 340_{SGD2}, and 340_{SGDi} can form four respective drain select gates of block 291. The drain select gates formed by conductive materials 340_{SGD1} and 340_{SGD2} in FIG. 3B are not shown in FIG. 2. As shown in FIG. 3B, conductive materials 340_{SGD0}-340_{SGDi} (FIG. 3B) can be electrically separated from each other by a gap 347 (which can be filled with a dielectric material (or materials)). For simplicity, FIG. 3B does not give labels for other conductive materials that form respective select gates and control gates of blocks 290 and 292.

The four conductive materials 340_{SGD0}, 340_{SGD1} and 340_{SGD2} and 340_{SGDi} included in four respective drain select gates on the same level in block 291 can be associated with four respective sub-blocks of block 291. FIG. 3B shows an example of memory device 200 including four drain select gates in each block (e.g., block 291) formed by four corresponding conductive materials 340_{SGD0}, 340_{SGD1}, 340_{SGD2}, and 340_{SGDi} on the same level (e.g., level 376 in FIG. 3C). However, the number of drain select gates on the same level in a block of memory device 200 can be different from four. For example, the number of drain select gates on the same level in a block can be based on (e.g., equal to) the number of sub-blocks in a block.

Line 3C-3C in FIG. 3B shows a location of a portion (e.g., a side view (e.g., a cross-section)) of memory device 200 shown in FIG. 3C.

As shown in FIG. 3C, memory device 200 can include levels 362, 364, 366, 372, 374, and 376 that are physical layers (e.g., portions) in the Z-direction of memory device 200. Conductive materials 340_{SGS}, 340₀-340_{M}, and 340_{SGD0}-340_{SGDi} can be located (e.g., stacked) one level (e.g., one layer) over another in respective levels 362, 364, 366, 372, 374, and 376 in the Z-direction. Conductive materials 340_{SGS}, 340₀-340_{M}, and 340_{SGD0}-340_{SGDi} can also be called levels of conductive materials 340_{SGS}, 340₀-340_{M}, and 340_{SGD0}-340_{SGDi}. As shown in FIG. 3C, conductive materials 340_{SGD0}-340_{SGDi} can be located on the same level (e.g., level 376).

As shown in FIG. 3C, conductive materials 340_{SGS}, 340₀-340_{M}, and 340_{SGDi} can interleave with dielectric materials 341 in the Z-direction. Dielectric materials 341 can include silicon dioxide. Conductive materials 340_{SGS}, 340₀-340_{M}, and 340_{SGDi} can include metal (e.g., tungsten, or other metal), other conductive materials, or a combination of conductive materials.

Signals SGS, WL₀, WL₁, WL_{M-1}, WL_{M}, SGD₀, and SGDᵢ in FIG. 3C associated with respective conductive materials in FIG. 3C are the same signals shown in FIG. 2. Conductive material 340_{SGS} can form select gate 280 (associated with signal SGS) of FIG. 2. Conductive materials 340₀-340_{M} can form control gates 250₀ through 250_{M} (associated with signals WL₀, WL₁, WL_{M-1}, and WL_{M}, respectively) of FIG. 2. Conductive material 340_{SDG0} and 340_{SGDi} (associated with signals SGD₀, and SGDᵢ) can form select gates 281₀ and 281ᵢ, respectively, of FIG. 2.

FIG. 3C shows an example of memory device 200 including one level of conductive materials 340_{SGS} that forms a select gate (e.g., source select gate associated with signal SGS). However, memory device 200 can include multiple levels (similar to level 362) of conductive materials (e.g., multiple levels of conductive material 340_{SGS}) located under (in the Z-direction) the level of conductive materials 340₀ (e.g., below level 364) to form multiple source select gates of memory device 200.

FIG. 3C shows an example of memory device 200 including one level (e.g., level 376) of multiple drain select gates (on the same level, formed by respective conductive materials 340_{SGD0}-340_{SGDi}). However, memory device 200 can include multiple levels (similar to level 376) in which each of such multiple levels can include multiple drain select gates (e.g., four drain select gates in each of the multiple levels).

As shown in FIG. 3C, memory device 200 can include a staircase structure 333 located in staircase region 345 (FIG. 3B shows a top view of staircase region 345). For simplicity, only a portion of staircase structure 333 is shown in FIG. 3C (e.g., a middle portion of staircase structure 333 is omitted from FIG. 3C). As shown in FIG. 3C, respective portions (e.g., end portions) of conductive materials 340_{SGS} and 340₀-340_{M} and their respective edges (e.g., steps (or risers)) 340E1, 340E2, and 340E3, 340E4, and 340E5 can collectively form staircase structure 333. As shown in FIG. 3C, dielectric materials 341 can also include edges (not labeled) adjacent (e.g., aligned in the Z-direction with) respective edges 340E1, 340E2, and 340E3, 340E4, and 340E5. Thus, staircase structure 333 can also be formed in part by portions and edges (e.g., edges that are aligned with edges 340E1, 340E2, and 340E3, 340E4, and 340E5) of dielectric materials 341.

FIG. 3C also shows tiers of memory device 200. A tier of memory device 200 can include a level of conductive material (e.g., conductive material 340₁) and an adjacent level of dielectric material 341 (e.g., dielectric material 341 between conductive materials 340₀ and 340₁). As shown in FIG. 3C, the tiers can be located (e.g., stacked) one over another in the Z-direction over substrate 399. Each tier can have respective memory cells 202 (which are located on the same level (same tier) with respect to the Z-direction). Each tier can have a respective control gate (e.g., a respective word line) for memory cells 202 of the respective tier. The control gate in a tier is formed by a respective level of conductive material among conductive materials 340₀-340_{M}. FIG. 3C shows a few tiers of memory device 200 for simplicity. However, memory device 200 can include up to (or more than) one hundred tiers.

Other blocks (e.g., blocks 290 and 292 in FIG. 3B) of memory device 200 can also have their own tiers of memory cells 202 and respective control gates (e.g., respective word lines) for the memory cells, and staircase structures similar to staircase structure 333 in block 291 in FIG. 3C. For simplicity, details of staircase structures of the other blocks of memory device 200 are omitted from the description herein.

As shown in FIG. 3C, memory device 200 can include a substrate 399 and materials 396 and 397 located over (e.g., formed over) substrate 399. Substrate 399 can include semiconductor (e.g., silicon) substrate. Substrate 399 can also include circuitry 395 located under other components of memory device 200 that are formed over substrate 399. Circuitry 395 can include circuit elements (e.g., transistors Tr1 and Tr2 shown in FIG. 3C) coupled to circuit elements outside substrate 399. For example, the circuit elements outside substrate 399 can include data lines 270₀ through 270_{N} (shown in FIG. 3A) conductive contacts 365_{SGS}, 365₀-365_{M}, 365_{SGD0} through 365_{SGDi} (FIG. 3B), part of conductive paths 391 and other (not shown) conductive connections, and other circuit elements of memory device 200. The circuit elements (e.g., transistors Tr1 and Tr2) of circuitry 395 can be configured to perform part of a function of memory device 200. For example, transistors Tr1 and Tr2 can form or can be part of decoder circuits, driver circuits (e.g., drivers 140 in FIG. 1), buffers, sense amplifiers, charge pumps, and other circuitry of memory device 200.

As shown in FIG. 3C, conductive paths (e.g., conductive routings) 391 of memory device 200 can include portions extending in the Z-direction (e.g., extending vertically). Conductive paths 391 can include (e.g., can be coupled to) some of the conductive contacts (e.g., conductive contacts 365_{SGS}, 365₁-365_{M}, and 365_{SGD0}-365_{SGDi} in FIG. 3B) or all of the conductive contacts of memory device 200. As shown in FIG. 3C, conductive paths 391 can be coupled to circuitry 395. For example, at least one of conductive paths 391 can be coupled to at least one of transistors Tr1 and Tr2 of circuitry 395.

Conductive paths 391 can provide electrical connections between elements of memory device 200. For example, conductive paths 391 can be coupled to conductive contacts 365_{SGS}, 365₀-365_{M-1}, and 365_{SGD0}-365_{SGDi} and circuit elements (e.g., word line drivers and word line decoders, not shown) of circuitry 395 to provide electrical connections (e.g., in the form of signals SGS, WL₀ through WL_{M}, and SGD₀ through SGDᵢ) from circuit elements (e.g., word line drivers, word line decoders, and charge pumps, not shown) in circuitry 395 to conductive contacts 365_{SGS}, 365₀-365_{M}, and 365_{SGD0}-365_{SGDi}, respectively.

As shown in FIG. 3C, conductive contacts 365_{SGS} and 365₀-365_{M} can include pillars (e.g., conductive pillars) that can have different lengths extending in the Z-direction (e.g., extending vertically (e.g., outward) from substrate 399). For simplicity, FIG. 3C shows a label for pillar 365P for only one of conductive contacts 365₀-365_{M}. Each of conductive contacts 365_{SGS} and 365₀-365_{M} (including a respective pillar) can contact (e.g., land on) a respective level of a particular conductive material (among conductive materials 340_{SGS}, 340₀-340_{M}) at the location of staircase structure 333. Each conductive contact 365_{SGS} and 365₀-365_{M} can form an electrical contact with a respective conductive material (among conductive materials 340_{SGS}, 340₀-340_{M}). Thus, conductive contacts 365_{SGS}, 365₀-365_{M} (and 365_{SGD0}-365_{SGDi} shown in FIG. 3B) can be part of conductive paths (e.g., part of conductive paths 391) to carry electrical signals to the select gate (e.g., source select gate associated with signal SGS), the control gates (e.g., control gates associated with signals WL_{M} and WL_{M-1}) and other select gates (e.g., drain select gates associated with signals SGD₀-SGDᵢ), respectively.

As shown in FIG. 3C, conductive contact 365_{SGS} is electrically in contact with conductive materials 340_{SGS} and electrically separated from the rest of conductive materials (e.g., conductive materials 340₀-340_{M} and 340_{SGD0}-340_{SGDi}). Conductive contact 365₀ is electrically in contact with conductive materials 340₀ and electrically separated from the rest of conductive materials (e.g., conductive materials 340_{SGS}, 340₁, 340_{M-1}, 340M, and 340_{SGDi}). Thus, a conductive contact (e.g., conductive contact 365₀) can be electrically in contact with only one of the conductive materials among the conductive materials (e.g., conductive materials 340_{SGS}, 340₀-340_{M}, and 340_{SGD0}-340_{SGDi} in FIG. 3C) of memory device 200.

Materials 396 and 397 (FIG. 3C) can be part of source (e.g., a source line, a source plate, or a source region) 298 (FIG. 2) of memory device 200. Materials 396 and 397 can include different conductive materials. An example of material 396 includes tungsten silicide. An example of material 397 includes polysilicon. Materials 396 and 397 can include other conductive materials. Material 397 can include multiple levels (e.g., layers) of materials in the Z-direction. For example, material 397 can include levels (e.g., layers) of polysilicon interleaved with levels (e.g., layers) of oxide (e.g., silicon dioxide). Materials 396 and 397 can be used to form electrical connections (e.g., lateral connections in the X-direction or the Y-direction) between elements (e.g., contact structures 344 and other elements) of memory device 200 in circuitry 395.

As shown in FIG. 3C, pillar (memory cell pillar) 330 can include a structure 335 extending along the length (in the Z-direction) of pillar 330 and coupled to a respective data line (e.g., data line 270_{N-1} or 270_{N}) and the source (which includes materials 396 and 397) of memory device 200. Structure 335 can include a conductive channel portion that can be part of a conductive path between a respective data line (e.g., data line 270_{N}) and the source (e.g., includes materials 396 and 397) to carry current (e.g., current between data line 270_{N} and materials 396 and 397) during an operation (e.g., read, write, or erase) of memory device 200.

Structure 335 of pillar 330 can include multiple layers of different materials that can be part of a TANOS (TaN, Al₂O₃, Si₃N₄, SiO₂, Si) structure of pillar 330 or a structure similar to a TANOS structure. For example, structure 335 can include a dielectric portion (e.g., interpoly dielectric portion). The dielectric portion can include a charge blocking material or materials (e.g., a dielectric material including TaN and Al₂O₃) that are capable of blocking a tunneling of a charge. Structure (e.g., TANOS structure) 335 can include a charge storage portion. The charge storage portion can include a charge storage element (e.g., charge storage material or materials, e.g., Si₃N₄) that can provide a charge storage function (e.g., trap charge) to represent a value of information stored in a respective memory cell 202. Structure (e.g., TANOS structure) 335 can include another dielectric portion (where the charge storage portion can be between the dielectric portions) that can include a tunnel dielectric material or materials (e.g., SiO₂). The tunnel dielectric material (or materials) is capable of allowing tunneling of a charge (e.g., electrons). In an alternative structure of memory device 200, structure 335 of pillar 330 can include or can be part be part of a SONOS (Si, SiO₂, Si₃N₄, SiO₂, Si) structure. In another alternative structure of memory device 200, structure 335 of pillar 330 can include or can be part of a floating gate structure. For example, structure 335 can include a charge storage portion that can include polysilicon (or other material) that can be part of a floating gate of a respective memory cell 202.

As shown in FIG. 3C, contact structures 344 can include respective pillars 344P that have lengths extending in the Z-direction (e.g., extending vertically (e.g., outward) from substrate 399). Contact structures 344 (including pillars 344P) can have the same length. Contact structures 344 can go through a respective portion of (e.g., go through respective holes in the tiers of) conductive materials 340_{SGS} and 340₀-340_{M} and dielectric materials 341. Thus, pillars 344P of contact structures 344 can be formed in holes in the tiers of memory device 200. Contact structures 344 are electrically separated from (not electrically coupled to) conductive materials 340_{SGS} and 340₀-340_{M}. Contact structures 344 can be coupled to (e.g., electrically coupled to) respective portions of materials 396 and 397 of the source (associated with signal SL) of memory device 200.

Contact structures 344 can also be coupled to respective conductive portions 394. Conductive portion 394 can include a conductive material (e.g., tungsten or other metals). Conductive portion 394 can be coupled to other elements of memory device 200. For example, conductive portion 394 can be electrically coupled to elements (e.g., transistors Tr1 and Tr2) of circuitry 395. FIG. 3C also shows dielectric materials (e.g., silicon dioxide spacers) 381 formed in different locations in materials 396 and 397. Dielectric materials 381 can be formed to selectively separate (e.g., laterally separate) materials 396 and 397 into different portions. In FIG. 3C, a portion labeled “FIG. 3D” and “FIG. 3F” are shown in detail in FIG. 3D and FIG. 3F, respectively.

FIG. 3D shows detail of a portion (e.g., a side view (a cross-section)) of contact structure 344 including pillar 344P that can include a dielectric liner portion 344L and a core portion 344C. FIG. 3E shows a top view (e.g., a cross-section parallel to the X-Y plane) of contact structure 344 along line 3E-3E of FIG. 3D. The following description refers to FIG. 3D and FIG. 3E. As shown in FIG. 3D and FIG. 3E, core portion (conductive core portion) 344C is adjacent dielectric liner portion 344L (e.g., interfaces with an inner surface of dielectric liner portion 344L). As shown in FIG. 3E, core portion 344C can be surrounded by dielectric liner portion 344L with respect to the top view (e.g., X-Y plane view). With respect to the view (e.g., side view) shown in FIG. 3D, at least a portion (e.g., left and right portions) of core portion 344C can be surrounded (e.g., surrounded on the left and right sides) by dielectric liner portion 344L.

As shown in FIG. 3D and FIG. 3E, dielectric liner portion 344L is a multi-layer dielectric liner that can include a dielectric material (e.g., a layer of material) 721, a dielectric material (e.g., a layer of material) 822 adjacent (e.g., contacting) dielectric material 721, and a dielectric material (e.g., a layer of material) 921 adjacent (e.g., contacting) dielectric material 721. Dielectric material 822 is between (e.g., sandwiched between) dielectric materials 721 and 921. Dielectric material 822 is different from dielectric materials 721 and 921. Dielectric materials 721 and 921 can include a same dielectric material that is different from dielectric material 822. Alternatively, dielectric materials 721 and 921 can include different dielectric materials. In an example, dielectric material 721 includes an oxide material (e.g., silicon dioxide material). In an example, material 822 includes a nitride material (e.g., silicon nitride material). In an example, dielectric material 921 includes an oxide material (e.g., silicon dioxide material). Thus, in an example, Dielectric materials 721, 822, and 921 include silicon oxide, silicon nitride, and silicon oxide, respectively. However, other suitable dielectric materials can be used for dielectric materials 721, 822, and 921.

Dielectric materials 721, 822, and 921 can have a thickness relationship. For example, dielectric material 822 can have a thickness (e.g., in the Y-direction in FIG. 3D) less than the thickness of each of dielectric material 721 and dielectric material 921. As an example, dielectric materials 721, 822, and 921 can have a thickness relationship such that the thickness (e.g., in nanometer unit) of dielectric material 822 can be from one-fourth (¼) to one-half (½) of the thickness of each of dielectric materials 721 and 921.

In some structures of memory device 200, structuring (e.g., forming) dielectric materials 721, 822, and 921 with certain materials (e.g., silicon oxide, silicon nitride, and silicon oxide, respectively) at a certain thickness relationship (e.g., thickness relationship described above) can maintain or improve the electrical properties (e.g., electric field, breakdown voltage, or both) of contact structure 344.

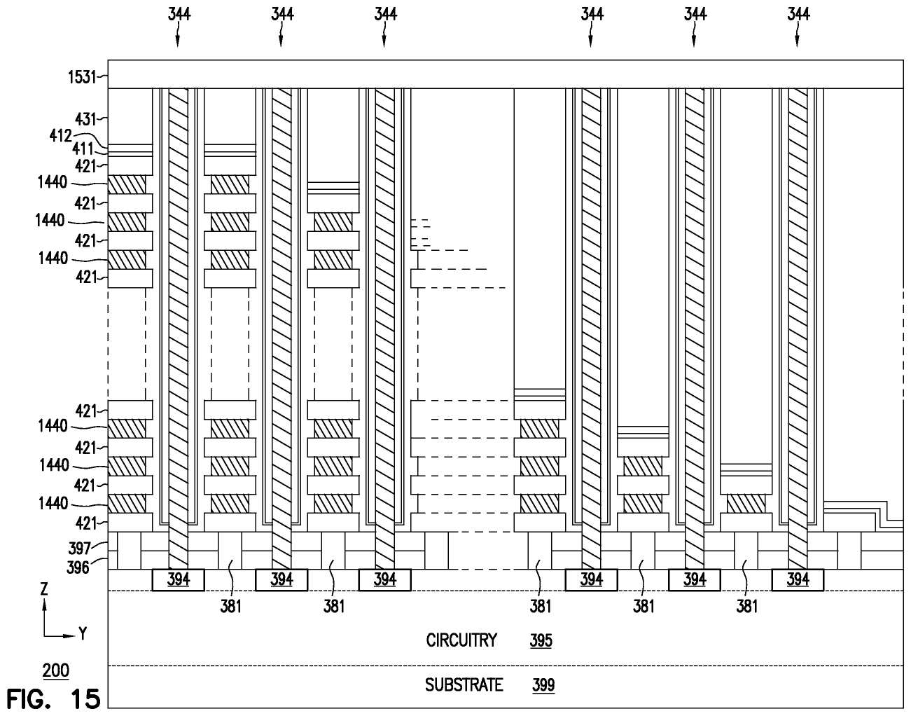

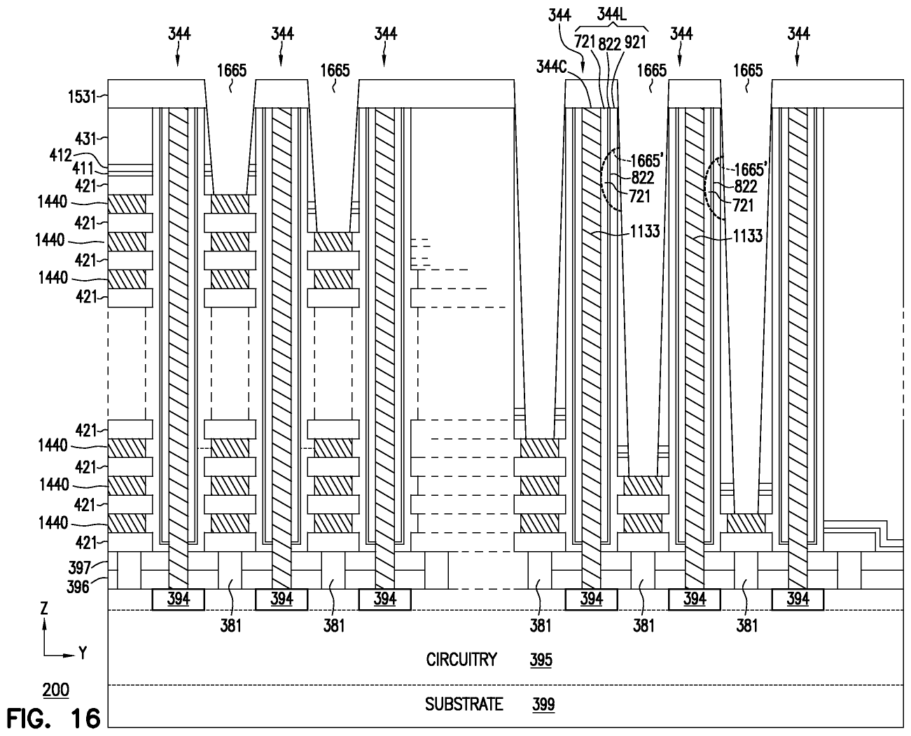

Further, structuring (e.g., forming) dielectric materials 721, 822, and 921 with certain materials (e.g., silicon oxide, silicon nitride, and silicon oxide, respectively) at a certain thickness relationship (e.g., thickness relationship described above) can also allow dielectric liner portion 344L to prevent potential damage to the structure of contact structure 344 during part of formation of adjacent elements (e.g., part of formation of conductive contacts 365₀-365_{M}) of memory device 200, as described below with respect to FIG. 15 through FIG. 20.

As shown in FIG. 3D and FIG. 3E, core portion 344C of contact structure 344 can include a material (e.g., a layer of material) 1133A, a material (e.g., a layer of material) 1133B, and a material 1133C adjacent each other as shown in FIG. 3E. Materials 1133A, 1133B, and 1133C (e.g., three different materials) can be collectively called a material (or materials) 1133. As shown in FIG. 3E, material 1133 can be surrounded by dielectric material 921 of dielectric liner portion 344L and can contact (e.g., directly coupled to) dielectric liner portion 344L. For example, material 1133A of core portion 344C can contact (e.g., be directly coupled to) dielectric material 921 of dielectric liner portion 344L.

Core portion 344C is a conductive structure, such that material 1133 (e.g., at least one of materials 1133A, 1133B, and 1133C) can include a conductive material. At least one of materials 1133A, 1133B, and 1133C can include a metal material or an alloy. For example, materials 1133A, 1133B, and 1133C can include titanium, titanium nitride, and tungsten, respectively, or other suitable material.

One or more of materials 1133A, 1133B, and 1133C can be omitted as long as core portion 344C can remain a conductive structure. Thus, core portion 344C can include fewer than all of materials 1133A, 1133B, and 1133C as long as core portion 344C can remain a conductive structure. For example, core portion 344C may include only material 1133C (e.g., tungsten). Alternatively, core portion 344C can include an additional conductive material (or multiple additional conductive materials) besides materials 1133A, 1133B, and 1133C.

FIG. 3F shows detail of a portion (e.g., a side view (a cross-section)) of a conductive contact 365₁ including pillar 365P. FIG. 3G shows a top view (e.g., a cross-section parallel to the X-Y plane) along line 3G-3G of FIG. 3F. The following description refers to FIG. 3F and FIG. 3G. As shown in FIG. 3F, pillar 365P can include a dielectric liner portion 365L and a core portion (conductive core portion) 365C. Core portion 365C is adjacent dielectric liner portion 365L (e.g., interface with an inner surface of dielectric liner portion 365L). As shown in FIG. 3G, core portion 365C can be surrounded by dielectric liner portion 365L with respect to the top view (e.g., X-Y plane view). With respect to the view (e.g., side view) shown in FIG. 3F, at least a portion (e.g., left and right portions) of core portion 365C can be surrounded (e.g., surrounded on the left and right sides) by dielectric liner portion 365L.

Dielectric liner portion 365L of conductive contact 365₁ can include a material (e.g., a layer of material) 1721. Material 1721 can include a dielectric material. For example, material 1721 can include an oxide material (e.g., silicon dioxide). FIG. 3F and FIG. 3G show an example of dielectric liner portion 365L including dielectric material 1721 (e.g., a single layer of dielectric material surrounding core portion 365C). However, dielectric liner portion 365L can include an additional layer of dielectric material (or multiple layers of dielectric materials) besides material 1721. In an example, dielectric liner portion 365L can include a same structure as dielectric liner portion 344L of contact structure 344. Thus, in an example, dielectric liner portion 365L can include multiple materials (e.g., similar to or the same as dielectric materials 721, 822, and 921) surrounding core portion 365C.

Core portion 365C is a conductive structure, such that material 1933 can include a conductive material. Material 1933 can include metal, an alloy, or combination of metal and alloy). As an example, material 1933 can include tungsten. As shown in FIG. 3F, material 1933 can be surrounded by material 1721 of dielectric liner portion 365L and can contact (e.g., directly coupled to) material 1721 of dielectric liner portion 365L.

FIG. 3F and FIG. 3G show an example of core portion 365C including material 1933 (e.g., a single conductive material). However, core portion 365C can include an additional conductive material (or multiple conductive materials). For example, core portion 365C can include the structure of core portion 344C (e.g., same as the structure of core portion 344C of FIG. 3D and FIG. 3E), such that core portion 365C can include multiple conductive materials (e.g., two or more of materials 1133A, 1133B, and 1133C). Thus, core portion 365C can have a same structure as core portion 344C. Alternatively, core portion 365C can have a different structure from the structure of core portion 344C.

FIG. 4 through FIG. 20 show different views of structures during processes of forming memory device 200 of FIG. 2 through FIG. 3G, according to some embodiments described herein. The locations of the structure of memory device 200 in FIG. 4 through FIG. 20 can correspond to the location along line 4-4 of FIG. 3A.

FIG. 4 shows memory device 200 after conductive portions 394, dielectric materials 381, and materials 396 and 397 are formed over substrate 399. Conductive portions 394 can be electrically coupled to elements of circuitry 395 (as described above with reference to FIG. 3C). As described below, conductive structures 334L can be subsequently formed over respective conductive portions 394 and coupled to circuitry 395 through conductive portions 394.

FIG. 4 also shows dielectric materials 411 and 412, and dielectric materials 421 and 422 formed over (e.g., formed on) materials 396 and 397, and conductive portions 394. Dielectric materials 411 and 412 can include silicon nitride and silicon dioxide, respectively, that are formed over dielectric materials 421 and 422 after dielectric materials 421 and 422 are formed. Dielectric materials 412 and 411 are formed to prevent underlying conductive material (e.g., conductive material 1440 in FIG. 16) from etching or from over-etching that may damage the structure of that conductive material.

Dielectric materials 421 and dielectric materials 422 an be sequentially formed (e.g., deposited) one material after another over substrate 399 (e.g., and over materials 396 and 397) in an interleaved fashion. Dielectric materials 421 can include silicon dioxide. Dielectric materials 422 can include silicon nitride. As shown in FIG. 4, dielectric materials 421 and 422 can be formed, such that dielectric materials 421 can interleave with dielectric materials 422 on respective levels (e.g., levels 361, 362, 363, 364, 365, 366, 371, 372, 373, 374, 375, and 376) of memory device 200 in the Z-direction. Levels 362, 364, 366, 372, 374, and 376 are the same as those shown in FIG. 3C. For simplicity, FIG. 4 omits (does not show) some of dielectric materials 421 and 422 between levels 367 and 372.

As shown in FIG. 4, levels 361, 363, 365, 371, 373, and 375 are interleaved with levels 362, 364, 366, 372, 374, and 376. Dielectric materials (e.g., silicon dioxide) 421 can be formed on respective levels 361, 363, 365, 371, 373, and 375. Dielectric materials 422 (e.g., silicon nitride) can be formed on respective levels 362, 364, 366, 372, 374, and 376. Thus, the processes associated with FIG. 4 can include forming levels of materials (e.g., levels 361, 363, 365, 371, 373, and 375 of dielectric materials 421) interleaved with levels of additional materials (e.g., levels 362, 364, 366, 372, 374, and 376 of dielectric materials 422).

Dielectric materials 421 can correspond to dielectric materials 341 (FIG. 3C) between respective control gates (e.g., control gates associated signals WL₀-WL_{M} in FIG. 3C) of memory device 200. After memory device 200 is formed, dielectric materials 341 (FIG. 3C) are part of dielectric materials 421 of FIG. 4. Thus, the levels 361, 363, 365, 371, 373, and 375 of dielectric materials 421 in FIG. 4 are formed for electrically separating (in the Z-direction) respective control gates (e.g., control gates associated signals WL₀-WL_{M} in FIG. 3C) of memory device 200 from each other. The levels (e.g., levels 363 and 375) of dielectric materials 421 are also formed for electrically separating (in the Z-direction) the control gates from other elements (e.g., source select gate and drain select gate) of memory device 200.

FIG. 4 also shows part of dielectric materials 421 that was removed (e.g., etched) for forming a part of staircase structure 333. For example, staircase structure 333 can be formed in part by respective portions and edges of dielectric materials 421 that can correspond to the edges (aligned with edges 340E1, 340E2, and 340E3, 340E4, and 340E5) of dielectric materials 341 in FIG. 3C. The processes associated with FIG. 4 also form a dielectric material 431.

The following description with respect to FIG. 5 through FIG. 12 describes formation of contact structures 344 (FIG. 3D and FIG. 3E) including dielectric liner portion 344L (which includes dielectric materials 721, 822, and 921) and core portion 344C (which includes material 1133).

FIG. 5 shows memory device 200 after openings 544 are formed. Openings 544 are holes (e.g., deep holes) where contact structures 344 (FIG. 3C), can be subsequently formed. Each of openings (e.g., holes) 544 can include a depth in the Z-direction. Each of openings 544 can include a sidewall (e.g., vertical sidewall) 544W that includes respective portions of dielectric material 431 and dielectric materials 421 and 422. Forming openings 544 can include removing (e.g., etching) portions of dielectric material 431, and dielectric materials 421 and 422 at the locations of openings 544.

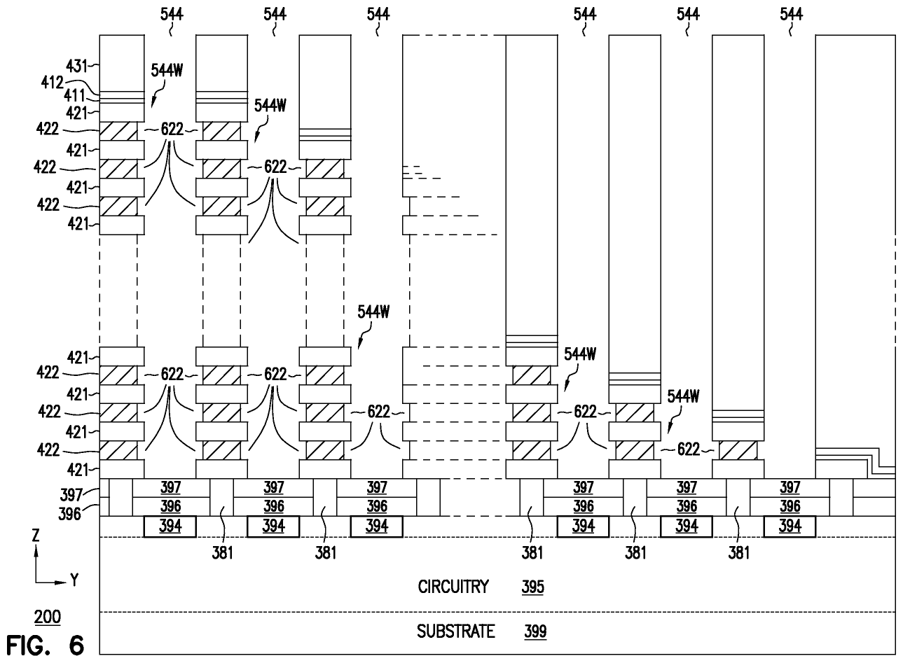

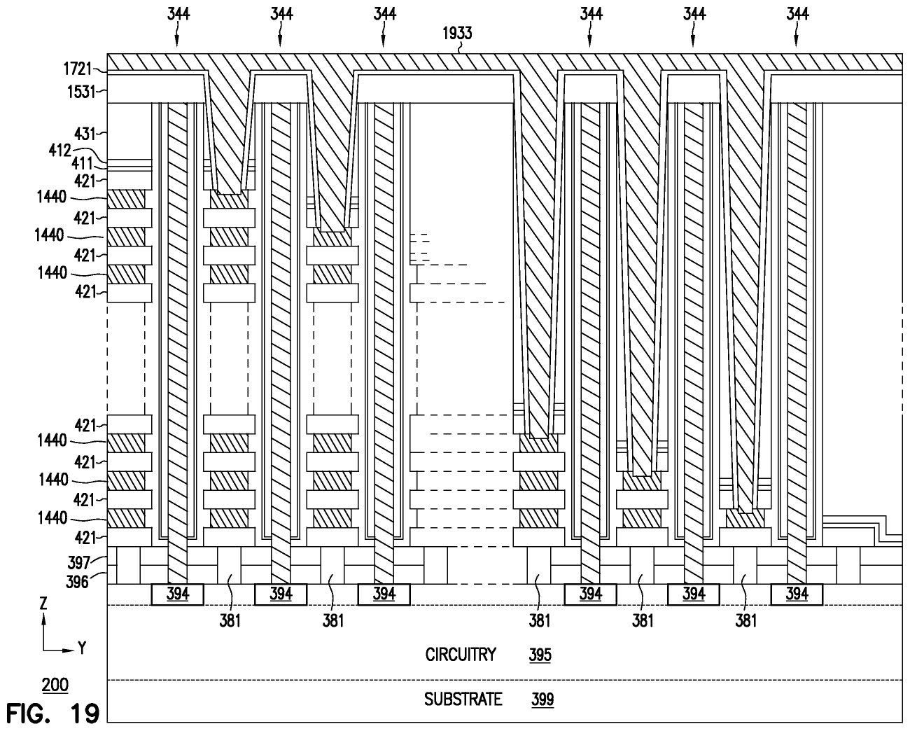

FIG. 6 shows memory device 200 after recesses (e.g., pockets) 622 are formed on respective levels (e.g., tiers) of memory device 200 along respective portions of sidewalls 544W of respective opening 544. Recesses 622 can be formed by removing (e.g., etching) respective portions of dielectric materials (e.g., silicon nitride) 422 that are exposed at openings 544 as shown in FIG. 6. As described in more detail below (associated with FIG. 19), recesses 622 are formed to create a distance (e.g., a wide enough margin) between the control gates and the core portions of contact structures 344 (FIG. 19). Such a distance created by recesses 622 can improve electrical functions of contact structures 344 (that are subsequently formed as described below).

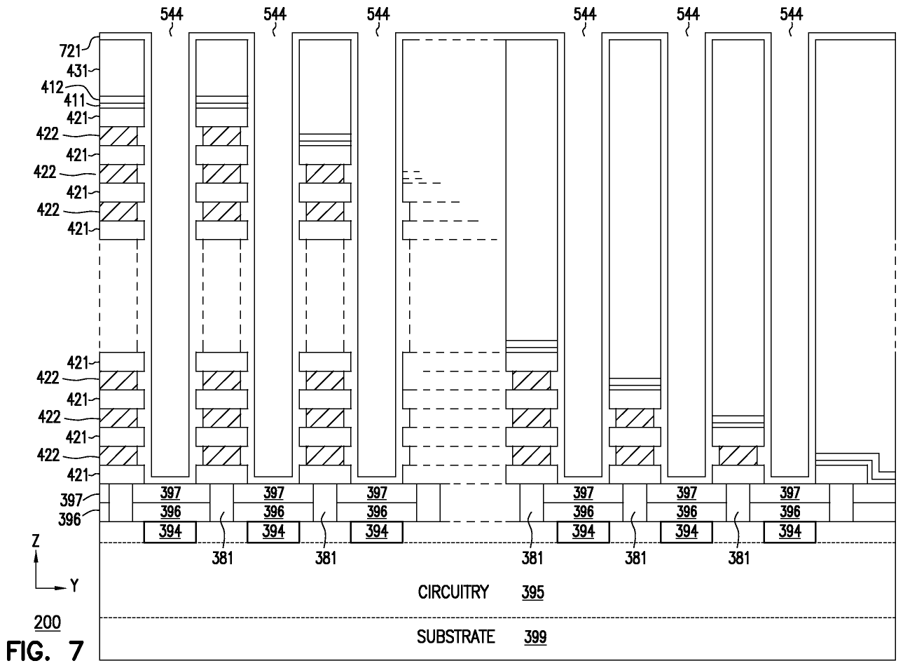

FIG. 7 shows memory device 200 after material (e.g., silicon dioxide) 721 is formed. Dielectric material 721 can be formed on sidewalls 544W (labeled in FIG. 6) of openings 544 and formed in (e.g., filled) recesses 622 (labeled in FIG. 6).

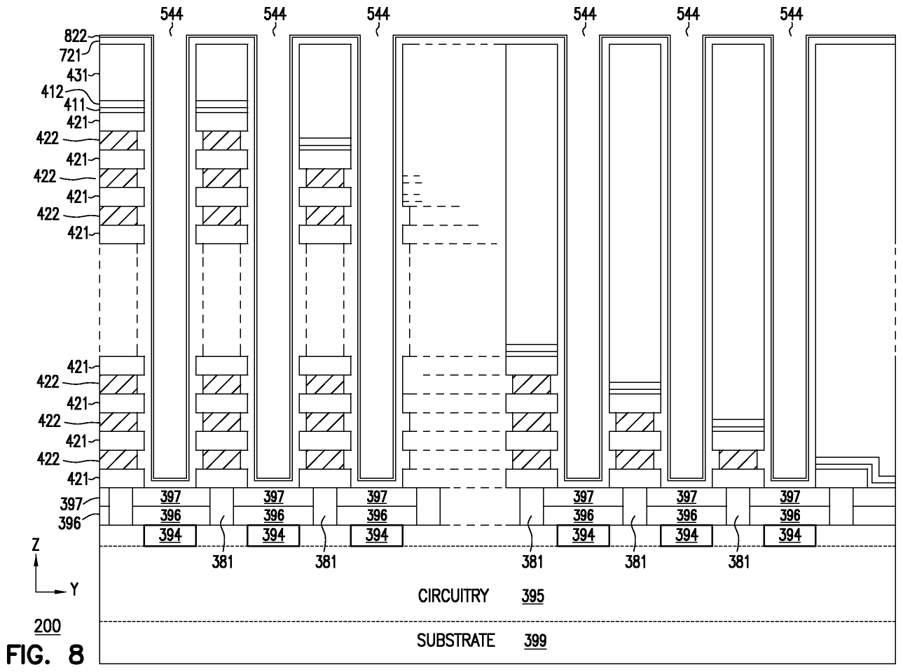

FIG. 8 shows memory device 200 after material (e.g., silicon nitride) 822 is formed on dielectric material 721. Dielectric material 822 can be a relatively thin layer of material that can form to dielectric material 721.

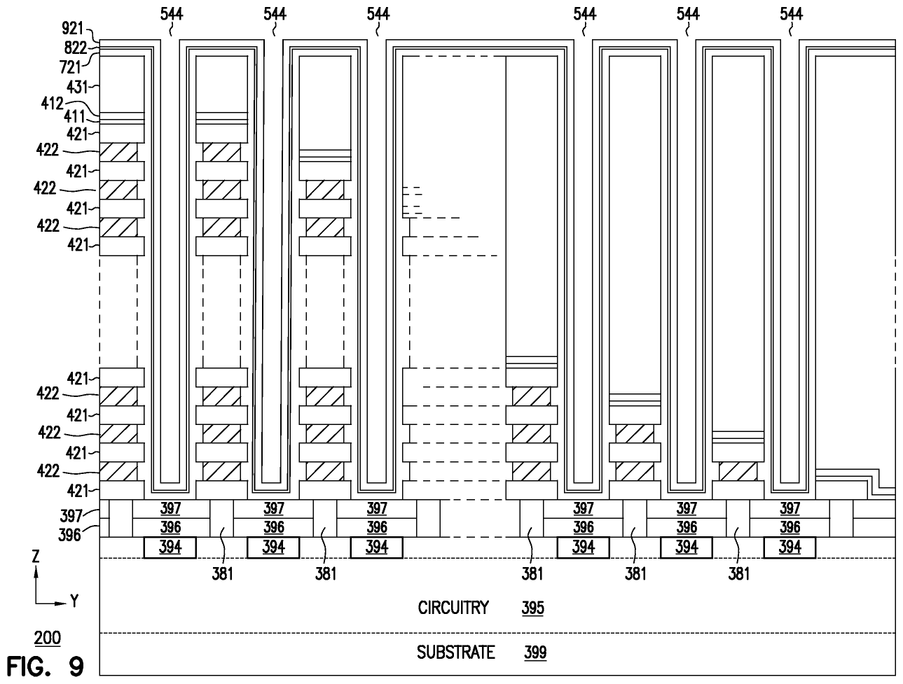

FIG. 9 shows memory device 200 after material (e.g., silicon dioxide) 921 is formed on dielectric material 822. Dielectric material 921 can conform to dielectric material 822.

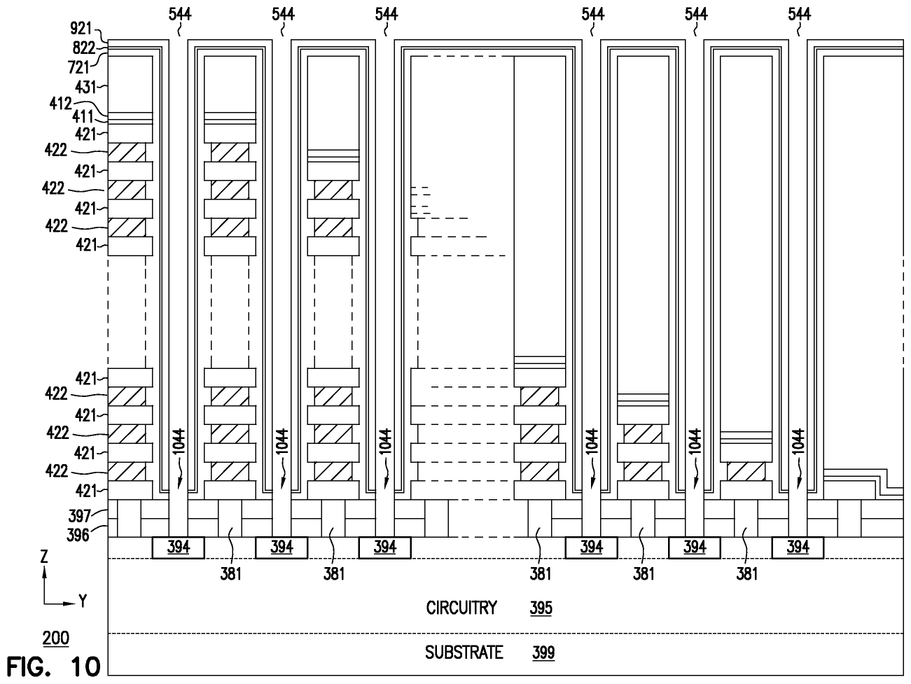

FIG. 10 shows memory device 200 after part of dielectric materials 721, 822, 921 and part of materials 396 and 397 at locations 1044 (at respective openings 544) are removed. For example, a punch-through process can be used in the processes associated with FIG. 10 to remove a portion (e.g., bottom portion) of dielectric material 721, a portion (e.g., bottom portion) of dielectric material 822, and a portion (e.g., bottom portion) of dielectric material 921, a portion of material 397, and a portion of material 396. As shown in FIG. 10, the process (e.g., punch-through process) can stop at conductive portions (e.g., tungsten) 394, such that conductive portions 394 are exposed at respective openings 544.

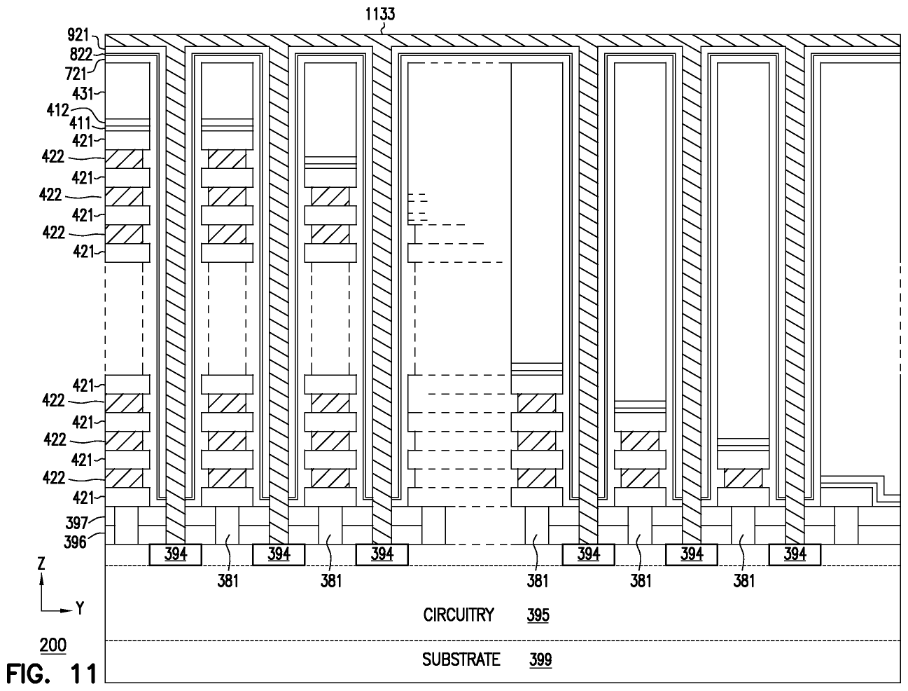

FIG. 11 shows memory device 200 after material (or materials) 1133 is formed. Materials 1133 can be formed on dielectric material 921 and formed in (e.g., filling) openings 544. As described above with reference to FIG. 3D and FIG. 3E, material 1133 can include different materials (e.g., multiple layers of materials) 1133A, 1133B, and 1133C (shown in FIG. 3D and FIG. 3F). Referring to FIG. 3D and FIG. 3E, materials 1133A, 1133B, and 1133C can be formed one after another in the processes associated with FIG. 11. For example, material 1133A (e.g., titanium) of FIG. 3E can be formed on material (e.g., silicon oxide) 921, and material 1133B (e.g., titanium nitride) of FIG. 3E can be formed on material 1133A (after material 1133A is formed). Then, material 1133C (e.g., tungsten) can be formed after material 1133B is formed.

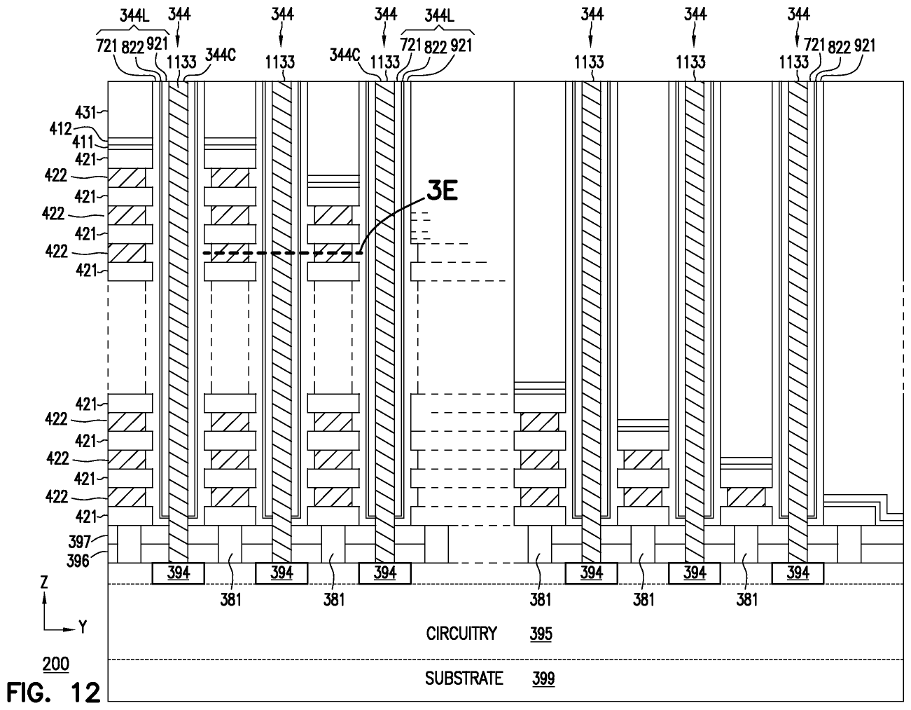

FIG. 12 shows memory device 200 after a portion (e.g., top portion) of each of material 1133, dielectric material 721, dielectric material 822, and dielectric material 921 is removed. For example, a chemical mechanical polishing or planarization (CMP) process can be used to remove a portion (e.g., top portion) of material 1133, a portion (e.g., top portion) of dielectric material 721, a portion (e.g., top portion) of dielectric material 822, and a portion (e.g., top portion) of dielectric material 921. A remaining portion (e.g., after a CMP process) of each of material 1133, dielectric material 721, dielectric material 822, and dielectric material 921 is shown in FIG. 12.

As shown in FIG. 12, contact structures 344 are formed. Each of contact structures 344 can include a dielectric liner portion 344L (which includes dielectric materials 721, 822, and 921) and a core portion (conductive core portion) 344C (which includes material 1133). A portion of a cross-section of one of contact structures 344 along line 3E is the same as the portion shown in FIG. 3E. Thus, for simplicity, the description in FIG. 12 omits detailed description of contact structures 344.

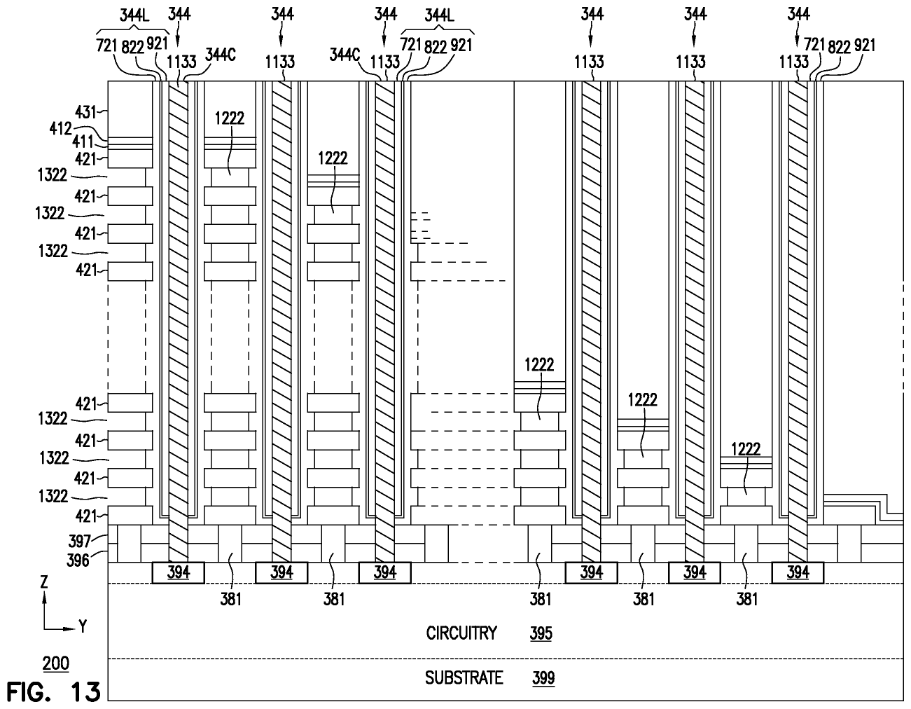

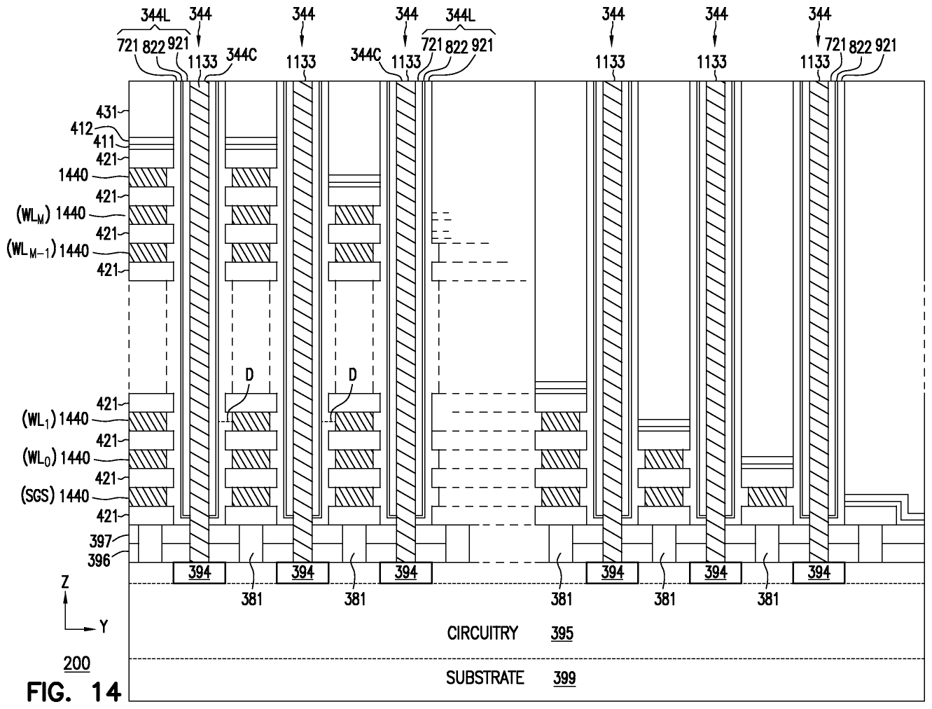

The following description with respect to FIG. 13 and FIG. 14 describes processes of forming conductive materials for respective control gates (e.g., control gates associated with signals WL₀-WL_{M} in FIG. 3C) and select gates (e.g., source select gates associated with signal SGS in FIG. 3C) of memory device 200.

FIG. 13 shows memory device 200 after dielectric material (e.g., silicon nitride) 422 is removed (e.g., exhumed) from locations 1322. Locations 1322 are empty spaces after dielectric materials 422 are removed. In subsequent processes, a conductive material (or conductive materials) can be formed in locations 1322 to form respective control gates and select gates (e.g., source select gates) of memory device 200.

FIG. 14 shows memory device 200 after a conductive material (or conductive materials) 1440 is formed in locations 1322. Forming conductive material 1440 can include depositing a single conductive material (e.g., tungsten or other metal) in locations 1322 (labeled in FIG. 13). Alternatively, the processes associated with FIG. 14 can include forming (e.g., depositing) multiple materials (one at a time) in locations 1322. For example, processes can include forming (e.g., depositing) aluminum oxide on sidewalls of locations 1322, forming (e.g., depositing) titanium nitride conformal to the aluminum oxide, and then forming (e.g., depositing) tungsten (or other suitable conductive material) to fill the rest of locations 1322. Thus, conductive material 1440 can include a combination of (multiple layers of) aluminum oxide, titanium nitride, and titanium.

In FIG. 14, conductive material 1440 at respective tiers (e.g., levels in the Z-direction) of memory device 200 can correspond to respective levels of conductive materials on levels (e.g., tiers) 362, 364, 366, 372, 374, 376 of FIG. 3C. For example, conductive material 1440 in FIG. 14 can correspond to respective conductive materials 340_{SGS} and 340₀-340_{M} on respective levels 362, 364, 366, 372, and 374 of memory device 200 shown in FIG. 3C. Thus, as shown in FIG. 14, control gates (associated with signals WL₀, WL₁, WL_{M-1}, and WL_{M}) and a select gate (e.g., source select gate associated with signal SGS) of block 291 are formed (formed from conductive material 1440 on respective levels of memory device 200).

As shown in FIG. 14, each contact structure 344 can be separated from an adjacent conductive material 1440 by a distance D (only two distances D are labeled). Distance D is part of the dimension (e.g., width in the X-direction) of recesses 622 formed in the processes associated with FIG. 6. Distance D can be selected to allow enough margin (in the X-direction) between core portions 344C of contact structures 344 and an adjacent conductive material 1440 of the control gates to improve electrical functions of contact structures 344. For example, the margin indicated by distance D can allow memory device 200 to maintain or improve bias voltage and electric field associated with contact structure 344.

FIG. 15 shows memory device 200 after a dielectric material 1531 is formed.

The following description with respect to FIG. 16 through FIG. 20 describes processes of forming the conductive contacts (e.g., conductive contacts 365_{SGS} and 365₀-365_{M} of FIG. 3C) of memory device 200.

FIG. 16 shows memory device 200 after openings 1665 are formed. Openings 1665 are holes that can have different depths in the Z-direction. Forming openings 1665 can include removing (e.g., etching) portions of dielectric materials 412 and 411, and portions of dielectric material 431 and dielectric materials (e.g., silicon dioxide) 421 from the locations of openings 1665. The processes of removing portions of dielectric material 431 and dielectric materials 421 can stop at conductive material 1440, such that openings 1665 can have respective bottoms at respective portions of conductive material 1440 at the locations of openings 1665. As mentioned above, dielectric materials 412 and 411 can prevent conductive material 1440 at the locations of openings 1665 from removal or from over-etching (in the processes of forming openings 1665) that may damage the structure of conductive material 1440.

As shown in FIG. 16, material (e.g., silicon nitride) 822 of dielectric liner portion 344L of a respective contact structure 344 is between an adjacent opening 1665 and material (silicon dioxide) 721 of dielectric liner portion 344L. Dielectric material 822 can have a different etch rate in comparison with dielectric material 721 and material 431. Thus, dielectric material 822 can be a shield to protect dielectric material 721 from a potential damage while openings 1665 are formed. For example, as shown in FIG. 16, some or all of openings 1665 may be formed with respective portions 1665′ that can have a relatively larger dimension (e.g., wider in diameter than an intended diameter). Without dielectric material 822, clipping of dielectric liner portion 344L may occur such that portion 1655′ may clip (cut into) part of dielectric material 721 adjacent portion 1665′ and cause damage to the structure of dielectric material 721. Such a clipping can expose material (conductive material) 1133 at the location of portion 1665′. This exposure can impact (e.g., degrade) the structure of contact structure 344. For example, a short (electrical short) may occur between core portion 334C (which includes material 1133) of contact structure 344 and other elements (e.g., conductive contacts 356₀-365_{M} that are subsequently formed at the locations of openings 1665). However, as shown in FIG. 16, since dielectric material 822 is between openings 1665 and dielectric material 721 of adjacent contact structures 344, dielectric material 822 can be a shield protecting dielectric material 721 from clipping by portion 1665′ or may reduce damage to dielectric material 721 caused by portion 1665′ even if portion 1665′ clips part of dielectric material 921 of dielectric liner portion 344L.

Thus, the inclusion of dielectric material 822 in dielectric liner portion 344L can prevent or reduce damage (e.g., a short between contact structures 344 and adjacent conductive contacts) to the structure of contact structure 344. This can improve or maintain the reliability of memory device 200 and improved yield. Moreover, since contact structures 344 including dielectric liner portion 344L are less susceptible to damage, scaling (e.g., block size reduction) in the structure of memory device 200 may not be limited by the structures of contact structures 344. This can provide a further option for features (e.g., block size) of memory device 200 to be scaled (e.g., reduced).

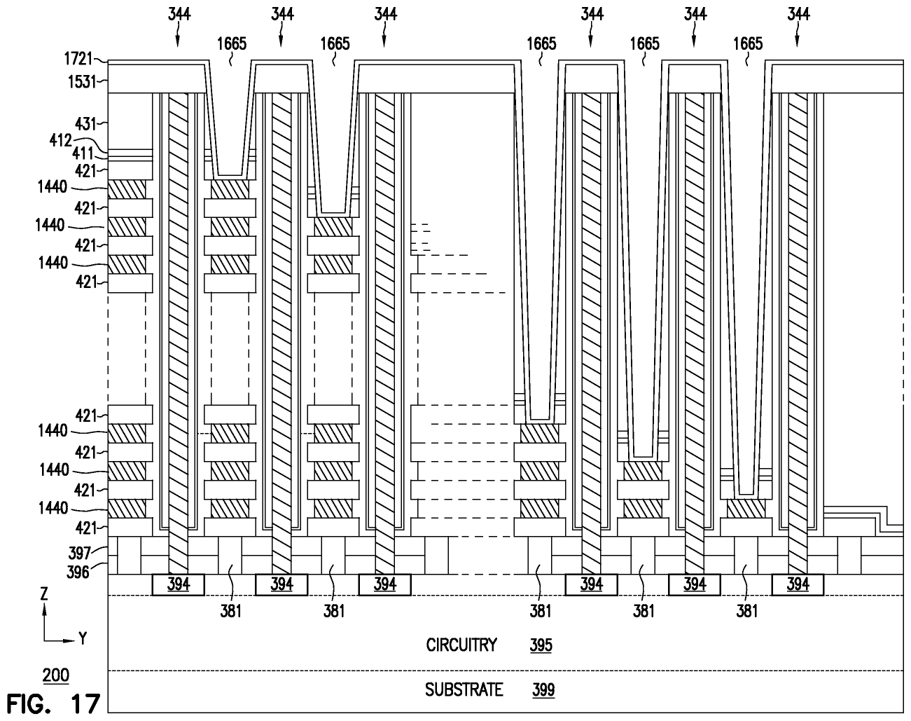

FIG. 17 shows memory device 200 after a material (e.g., silicon dioxide) 1721 is formed. Material 1721 can be formed on sidewalls of openings 1665.

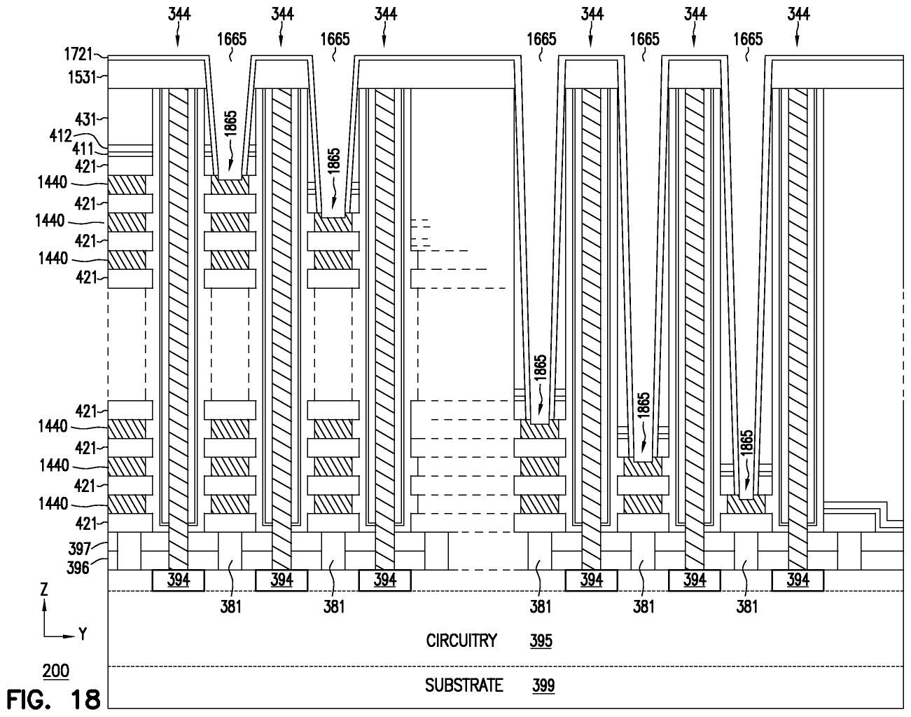

FIG. 18 shows memory device 200 after part of materials 1721 at locations 1865 (at respective openings 1665) are removed. In FIG. 18, at least a portion of conductive material 1440 at locations 1865 (at respective openings 1665) may also be removed. A punch-through process can be used in the processes associated with FIG. 18. As shown in FIG. 18, the process (e.g., punch-through process) can stop at conductive material 1440, such that conductive materials 1440 are exposed at respective openings 1665.

FIG. 19 shows memory device 200 after material (or materials) 1933 is formed. Materials 1933 can be formed on material 1721 and formed in (e.g., filling) openings 1665. As described above with reference to FIG. 3F and FIG. 3G, material 1933 can be similar to or the same as material 1133 of FIG. 11. For example, material 1933 of core portion (conductive core portion) 365C in FIG. 19 can include a single conductive material (e.g., metal (e.g., tungsten)) or multiple materials (e.g., titanium, titanium nitride, and tungsten, or other suitable materials).

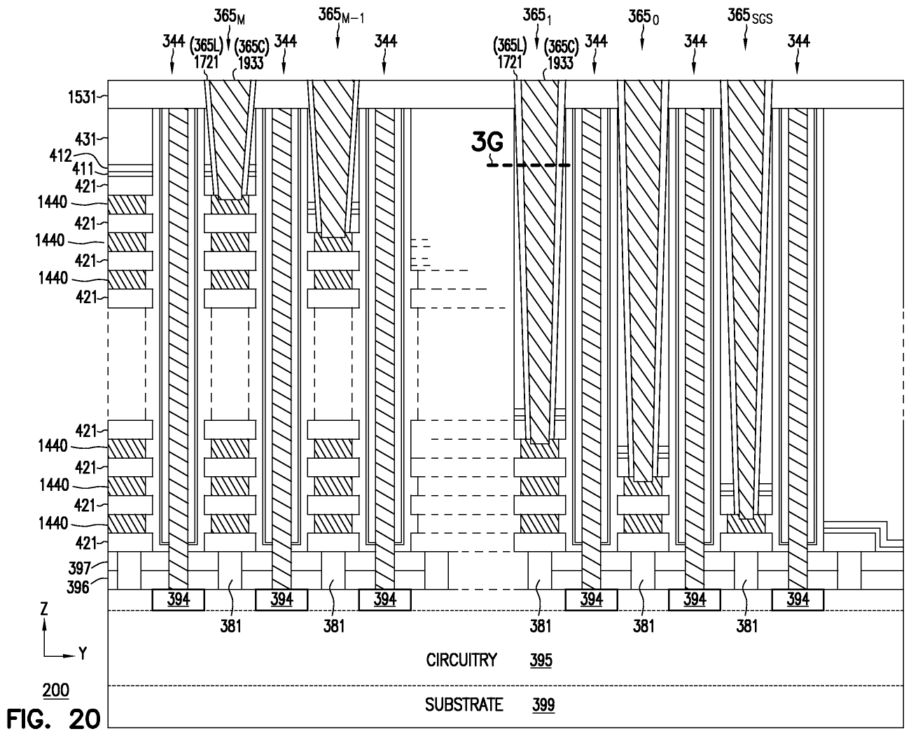

FIG. 20 shows memory device 200 after a portion (e.g., top portion) of each of material 1133 and material 1721 is removed (e.g., using a CMP process). A remaining portion (e.g., after a CMP process) of each of material 1133 and material 1721 is shown in FIG. 20.

As shown in FIG. 20, conductive contacts (e.g., conductive contacts 365_{SGS}, 365₀-365_{M}) of memory device 200 are formed. Each of contact structures 344 can include a dielectric liner portion 365L (which includes materials 1721) and a core portion 365C (which includes material 1933). A portion of a cross-section of one of conductive contacts 365_{SGS}, 365₀-365_{M} along line 3G is the same as the portion shown in FIG. 3G. Thus, for simplicity, the description in FIG. 20 omits detailed description of conductive contacts 365_{SGS}, 365₀-365_{M}.

Although not shown in FIG. 4 through FIG. 20, the processes of forming memory device 200 also include forming pillars 330 (FIG. 3C) of respective memory cell strings 230 (FIG. 3C). For example, the processes of forming memory device 200 also include forming memory cell strings 230 including forming respective pillars 330 of memory cell strings 230 before forming contact structures 344 (described above) and conductive contacts 365_{SGS}, 365₀-365_{M} (described above). Forming respective pillars 330 can includes forming holes in dielectric materials 421 and 422 (FIG. 4) then forming pillars 330 in the holes.

The process of forming memory device 200 as described above with reference to FIG. 4 through FIG. 20 can include additional processes after the processes associated with FIG. 19 are performed. For example, additional processes can include forming drain select gates and data lines and other elements and interconnections to complete the processes of forming memory device 200.

The illustrations of apparatuses (e.g., memory devices 100 and 200) and methods (e.g., methods of forming memory device 200) are intended to provide a general understanding of the structure of various embodiments and are not intended to provide a complete description of all the elements and features of apparatuses that might make use of the structures described herein. An apparatus herein refers to, for example, either a device (e.g., any of memory devices 100 and 200) or a system (e.g., an electronic item that can include any of memory devices 100 and 200).

Any of the components described above with reference to FIG. 1 through FIG. 20 can be implemented in a number of ways, including simulation via software. Thus, apparatuses (e.g., memory devices 100 and 200), or part of each of these memory devices described above, may all be characterized as “modules” (or “module”) herein. Such modules may include hardware circuitry, single- and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and ranges simulation package, a capacitance-inductance simulation package, a power/heat dissipation simulation package, a signal transmission-reception simulation package, and/or a combination of software and hardware used to operate or simulate the operation of various potential embodiments.

The memory devices (e.g., memory devices 100 and 200) described herein may be included in apparatuses (e.g., electronic circuitry) such as high-speed computers, communication and signal processing circuitry, single- or multi-processor modules, single or multiple embedded processors, multicore processors, message information switches, and application-specific modules including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 (Motion Picture Experts Group, Audio Layer 3) players), vehicles, medical devices (e.g., heart monitor, blood pressure monitor, etc.), set top boxes, and others.

The embodiments described above with reference to FIG. 1 through FIG. 20 include apparatuses and methods of forming the apparatuses. One of the apparatuses includes tiers located one over another, the tiers including respective memory cells and control gates for the memory cells; conductive contacts contacting the control gates, the conductive contacts having different lengths extending in a direction from one tier to another tier among the tiers; and a contact structure adjacent one of the conductive contacts. The contact structure includes a conductive core portion extending through the tiers and separated from the control gates, and a dielectric liner portion adjacent the conductive core portion. The dielectric liner portion includes a first dielectric material, a second dielectric material adjacent the first dielectric material, and a third dielectric material adjacent the second dielectric material. Other embodiments, including additional apparatuses and methods, are described.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B, and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B, and C” means A only; B only; or C only. Item A can include a single element or multiple elements. Item B can include a single element or multiple elements. Item C can include a single element or multiple elements.

In the detailed description and the claims, the terms “first,” “second,” and “third,” etc. are used merely as labels, and are not intended to impose numerical requirements on their objects.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

What is claimed is:

1. An apparatus comprising:
tiers located one over another, the tiers including respective memory cells and control gates for the memory cells;
conductive contacts contacting the control gates, the conductive contacts having different lengths extending in a direction from one tier to another tier among the tiers; and
a contact structure adjacent one of the conductive contacts, the contact structure including a conductive core portion extending through the tiers and separated from the control gates, and a dielectric liner portion adjacent the conductive core portion, the dielectric liner portion including a first dielectric material, a second dielectric material adjacent the first dielectric material, and a third dielectric material adjacent the second dielectric material.

2. The apparatus of claim 1, wherein the first and third dielectric materials are formed from a same material.

3. The apparatus of claim 1, wherein the first dielectric material includes silicon dioxide, and the second dielectric material includes silicon nitride.

4. The apparatus of claim 3, wherein the third dielectric material includes silicon dioxide.

5. The apparatus of claim 1, wherein the second dielectric material has a thickness less than a thickness of each of the first and second dielectric materials.

6. The apparatus of claim 1, wherein the conductive core portion includes metal.

7. The apparatus of claim 1, wherein each of the conductive contacts includes a dielectric liner portion having a different structure from the dielectric liner portion of the contact structure.

8. The apparatus of claim 7, wherein each of the conductive contacts includes a conductive core portion having a same structure as the conductive core portion of the contact structure.

9. The apparatus of claim 1, wherein the apparatus comprises a memory device, the memory device including circuitry located under the tiers, and the conductive core portion of the contact structure is coupled to the circuitry.

10. An apparatus comprising:
tiers located one over another, the tiers including respective memory cells and control gates for the memory cells, the control gates including respective portions that collectively form a staircase structure;
a first pillar including a conductive material extending in a direction from one tier to another tier among the tiers and contacting one of the control gates at a location of the staircase structure; and
a second pillar adjacent the first pillar and separated from the control gates, the second pillar including a conductive core portion and a dielectric liner portion adjacent the conductive core portion, the dielectric liner portion including a first dielectric material adjacent the conductive core portion, a second dielectric material adjacent the first dielectric material, and a third dielectric material adjacent the second dielectric material.

11. The apparatus of claim 10, wherein the second dielectric material includes silicon nitride.

12. The apparatus of claim 11, wherein the first and third dielectric materials include silicon dioxide.

13. The apparatus of claim 10, wherein the conductive core portion of the second pillar includes tungsten, and at least a portion of the tungsten is surrounded by the dielectric liner portion of the second pillar.

14. The apparatus of claim 10, wherein the conductive material of the first pillar includes tungsten.

15. The apparatus of claim 14, wherein the first pillar includes a dielectric liner portion surrounding at least a portion of the tungsten of the conductive material of the first pillar.

16. The apparatus of claim 10, wherein first pillar includes a conductive core portion having a different structure from a structure of the conductive core portion of the second pillar.

17. A method comprising:
forming levels of first dielectric materials interleaved with levels of second dielectric materials;
forming a contact structure through the levels of first dielectric materials and the levels of second dielectric materials, wherein forming the contact structure includes forming a dielectric liner portion and forming a conductive core portion adjacent the dielectric liner portion, the dielectric liner portion including silicon nitride material between a first silicon dioxide material and a second silicon dioxide material;
replacing the levels of second dielectric materials with respective levels of conductive materials, wherein the levels of conductive materials form respective control gates for memory cells of a memory device; and
forming a conductive contact adjacent the contact structure and contacting one of the levels of conductive materials.

18. The method of claim 17, wherein the conductive core portion includes a metal material.

19. The method of claim 17, wherein forming the dielectric liner portion includes:
forming an opening through the levels of first dielectric materials and the levels of second dielectric materials;
removing a portion of the levels of second dielectric materials exposed at the opening to form recesses;
forming the first silicon dioxide material in the recesses and on a sidewall of the opening;
forming the silicon nitride material on the first silicon dioxide material; and
forming the second silicon dioxide material on the silicon nitride material.

20. The method of claim 19, wherein forming the conductive core portion includes forming a metal material in the opening such that at least a portion of the metal material is surrounded by the dielectric liner portion.

21. A method comprising:
forming levels of first dielectric materials interleaved with levels of second dielectric materials, the levels of first dielectric materials having respective portions forming part of a staircase structure;
forming a contact structure in an opening in the levels of first dielectric materials and the levels of second dielectric materials at the staircase structure, wherein forming the contact structure includes forming a dielectric liner portion in the opening, and forming a conductive core portion in the opening such that at least a portion of the conductive core portion is surrounded by the dielectric liner portion, and forming the dielectric liner portion includes:
forming a first dielectric material in the opening;
forming a second dielectric material adjacent the first dielectric material; and
forming a third dielectric material adjacent the second dielectric material;
replacing the levels of second dielectric materials with respective levels of conductive materials, wherein the levels of conductive materials form respective control gates for memory cells of a memory device; and
forming a conductive contact adjacent the contact structure and contacting one of the levels of conductive materials.

22. The method of claim 21, wherein the second dielectric material includes silicon nitride.

23. The method of claim 22, wherein the first and third dielectric materials include silicon dioxide.

24. The apparatus of claim 21, wherein the levels of conductive materials include tungsten.

25. The method of claim 21, wherein the levels of first dielectric materials include silicon dioxide, and the levels of second dielectric materials include silicon nitride.
